(19) United States
(12) Patent Application Publication
(10) Pub. No.: US 2025/0203997 A1
(43) Pub. Date: Jun. 19, 2025

(54) SEMICONDUCTOR DEVICE AND METHOD OF MANUFACTURING THE SAME

(71) Applicant: Renesas Electronics Corporation, Tokyo (JP)

(72) Inventors: Takeshi KISHIDA, Tokyo (JP); Takehirou MARIKO, Tokyo (JP)

(21) Appl. No.: 18/931,211

(22) Filed: Oct. 30, 2024

(30) Foreign Application Priority Data
Dec. 18, 2023 (JP) 2023-212946

(51) Int. Cl. H01L 29/417; H01L 21/283; H01L 23/528; H01L 29/40; H01L 29/45; H01L 29/66; H01L 29/78

(52) U.S. Cl. CPC H10D 64/252; H01L 21/283; H01L 23/528; H10D 64/62; H10D 30/0291; H10D 30/668; H10D 64/117

(57) ABSTRACT

Since an electrode formed on an insulating film may be separated from the insulating film in a semiconductor device, the present invention makes it possible to prevent the separation of the electrode from the insulating film. A semiconductor device includes a semiconductor substrate, an insulating film, and an electrode. The insulating film is formed on the semiconductor substrate. The electrode is formed on the insulating film. The semiconductor device also includes an anchor member. The anchor member is in contact with the insulating film and the electrode, at an outer peripheral portion of the electrode.

### CROSS-REFERENCE TO RELATED APPLICATIONS

The disclosure of Japanese Patent Application No. 2023-212946 filed on Dec. 18, 2023 including the specification, drawings and abstract is incorporated herein by reference in its entirety.

### BACKGROUND

The present invention relates to a semiconductor device and a method of manufacturing a semiconductor device.

There are disclosed techniques listed below.
[Patent Document 1] Japanese Unexamined Patent Application Publication No. 2022-9698

For example, as a technique relating to a semiconductor device including a MOSFET (metal-oxide-semiconductor field-effect transistor), Patent Document 1 has been known. Patent Document 1 discloses that, in a semiconductor device constituting a trench gate-type MOSFET, a source electrode is formed on an insulating film on a semiconductor substrate and a source contact connecting a source region in the semiconductor substrate with the source electrode via the insulating film is formed.

### SUMMARY

However, in the related technique as Patent Document 1, the electrode formed on the insulating film may be separated from the insulating film.

Other objects and novel features will become apparent from the description of the present specification and the accompanied drawings.

According to one embodiment, a semiconductor device includes a semiconductor substrate, an insulating film formed on the semiconductor substrate, an electrode formed on the insulating film. Moreover, the semiconductor device includes an anchor member which is in contact with the insulating film and the electrode at an outer peripheral portion of the electrode, in plan view.

According to the one embodiment, it is possible to prevent separation of an electrode.

### BRIEF DESCRIPTION OF THE DRAWINGS

FIG. 1 is a plan view illustrating an outline of a semiconductor device according to an embodiment.

FIG. 2 is a cross-sectional view for describing the outline of the semiconductor device according to the embodiment.

FIG. 3 is a plan view illustrating a schematic configuration example of a semiconductor device according to a first embodiment.

FIG. 4 is an enlarged plan view illustrating a schematic configuration example of a semiconductor device of a comparative example.

FIG. 5 is a cross-sectional perspective view indicating an analysis result of an evaluation test according to the semiconductor device of the comparative example.

FIG. 6 is an enlarged plan view illustrating a schematic configuration example of the semiconductor device according to the first embodiment.

FIG. 7 is an enlarged plan view illustrating a schematic configuration example of the semiconductor device according to the first embodiment.

FIG. 8 is an enlarged plan view illustrating a schematic configuration example of the semiconductor device according to the first embodiment.

FIG. 9 is an enlarged plan view illustrating a schematic configuration example of the semiconductor device according to the first embodiment.

FIG. 10 is a cross-sectional view illustrating a schematic configuration example of the semiconductor device according to the first embodiment.

FIG. 11 is a cross-sectional view illustrating an example of a method of manufacturing the semiconductor device according to the first embodiment.

FIG. 12 is a cross-sectional view illustrating the example of the method of manufacturing the semiconductor device according to the first embodiment.

FIG. 13 is a cross-sectional view illustrating the example of the method of manufacturing the semiconductor device according to the first embodiment.

FIG. 14 is a cross-sectional view illustrating the example of the method of manufacturing the semiconductor device according to the first embodiment.

FIG. 15 is a cross-sectional view illustrating the example of the method of manufacturing the semiconductor device according to the first embodiment.

FIG. 16 is a cross-sectional view illustrating the example of the method of manufacturing the semiconductor device according to the first embodiment.

FIG. 17 is a cross-sectional view illustrating the example of the method of manufacturing the semiconductor device according to the first embodiment.

FIG. 18 is an enlarged plan view illustrating a schematic configuration example of a semiconductor device according to a second embodiment.

FIG. 19 is a cross-sectional view illustrating a schematic configuration example of the semiconductor device according to the second embodiment.

FIG. 20 is a cross-sectional view illustrating a schematic configuration example of the semiconductor device according to the second embodiment.

FIG. 21 is an enlarged plan view illustrating a schematic configuration example of the semiconductor device according to the second embodiment.

FIG. 22 is an enlarged plan view illustrating a schematic configuration example of the semiconductor device according to the second embodiment.

FIG. 23 is an enlarged plan view illustrating a schematic configuration example of the semiconductor device according to the second embodiment.

FIG. 24 is an enlarged plan view illustrating a schematic configuration example of the semiconductor device according to the second embodiment.

FIG. 25 is an enlarged plan view illustrating a schematic configuration example of the semiconductor device according to the second embodiment.

FIG. 26A is a cross-sectional view illustrating an example of a method of manufacturing the semiconductor device according to the second embodiment.

FIG. 26B is a cross-sectional view illustrating the example of the method of manufacturing the semiconductor device according to the second embodiment.

FIG. 27A is a cross-sectional view illustrating the example of the method of manufacturing the semiconductor device according to the second embodiment.

FIG. 27B is a cross-sectional view illustrating the example of the method of manufacturing the semiconductor device according to the second embodiment.

FIG. 28A is a cross-sectional view illustrating the example of the method of manufacturing the semiconductor device according to the second embodiment.

FIG. 28B is a cross-sectional view illustrating the example of the method of manufacturing the semiconductor device according to the second embodiment.

FIG. 29A is a cross-sectional view illustrating the example of the method of manufacturing the semiconductor device according to the second embodiment.

FIG. 29B is a cross-sectional view illustrating the example of the method of manufacturing the semiconductor device according to the second embodiment.

FIG. 30A is a cross-sectional view illustrating the example of the method of manufacturing the semiconductor device according to the second embodiment.

FIG. 30B is a cross-sectional view illustrating the example of the method of manufacturing the semiconductor device according to the second embodiment.

FIG. 31A is a cross-sectional view illustrating another example of the method of manufacturing the semiconductor device according to the second embodiment.

FIG. 31B is a cross-sectional view illustrating the another example of the method of manufacturing the semiconductor device according to the second embodiment.

FIG. 32A is a cross-sectional view illustrating the another example of the method of manufacturing the semiconductor device according to the second embodiment.

FIG. 32B is a cross-sectional view illustrating the another example of the method of manufacturing the semiconductor device according to the second embodiment.

FIG. 33A is a cross-sectional view illustrating the another example of the method of manufacturing the semiconductor device according to the second embodiment.

FIG. 33B is a cross-sectional view illustrating the another example of the method of manufacturing the semiconductor device according to the second embodiment.

FIG. 34A is a cross-sectional view illustrating the another example of the method of manufacturing the semiconductor device according to the second embodiment.

FIG. 34B is a cross-sectional view illustrating the another example of the method of manufacturing the semiconductor device according to the second embodiment.

FIG. 35 is an enlarged plan view illustrating a schematic configuration example of a semiconductor device according to a third embodiment.

FIG. 36 is a cross-sectional view illustrating a schematic configuration example of the semiconductor device according to the third embodiment.

FIG. 37 is an enlarged plan view illustrating a schematic configuration example of the semiconductor device according to the third embodiment.

FIG. 38 is an enlarged plan view illustrating a schematic configuration example of the semiconductor device according to the third embodiment.

FIG. 39 is an enlarged plan view illustrating a schematic configuration example of the semiconductor device according to the third embodiment.

FIG. 40 is an enlarged plan view illustrating a schematic configuration example of the semiconductor device according to the third embodiment.

FIG. 41 is an enlarged plan view illustrating a schematic configuration example of the semiconductor device according to the third embodiment.

FIG. 42 is an enlarged plan view illustrating a schematic configuration example of the semiconductor device according to the third embodiment.

FIG. 43 is an enlarged plan view illustrating a schematic configuration example of the semiconductor device according to the third embodiment.

FIG. 44 is an enlarged plan view illustrating a schematic configuration example of the semiconductor device according to the third embodiment.

FIG. 45 is an enlarged plan view illustrating a schematic configuration example of the semiconductor device according to the third embodiment.

FIG. 46 is an enlarged plan view illustrating a schematic configuration example of the semiconductor device according to the third embodiment.

### DETAILED DESCRIPTION

In the following, an embodiment will be described with reference to the attached drawings. Note that, for clarification of explanation, the description and the drawings described below are omitted and simplified appropriately. In addition, in each of the drawings, components having the same function are denoted by the same reference symbols, and the repetitive description thereof is omitted as needed.

In each of the drawings, an XYZ three-dimensional orthogonal coordinate system is indicated, and an XY plane formed by an X direction and a Y direction is a plane parallel to a plane of a semiconductor substrate (a front surface or a back surface). A Z direction orthogonal to the XY plane is a vertical direction, a height direction, or a thickness direction in the semiconductor substrate. “In plan view” means that the XY plane is viewed from the Z direction.

### Outline of Embodiment

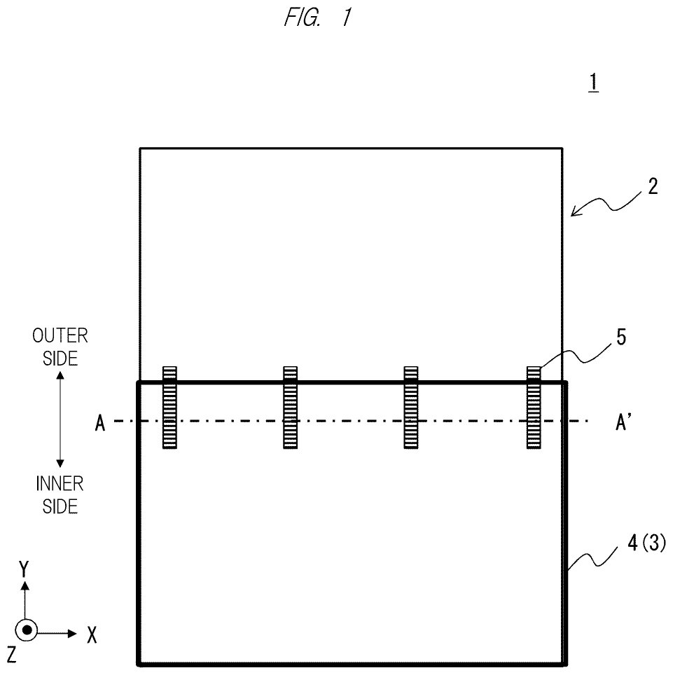

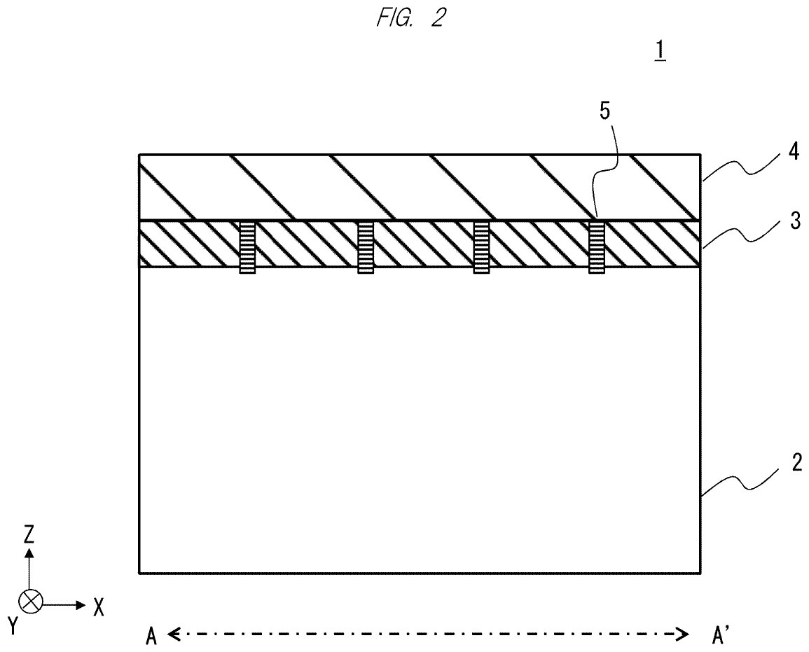

First, a description regarding the outline of the embodiment will be provided. FIG. 1 is a plan view illustrating a schematic configuration of a semiconductor device 1 according to the embodiment. FIG. 1 indicates a state in which an insulating film and an electrode on the semiconductor substrate are seen through. FIG. 2 is a cross-sectional view taken along a line A-A′ in the semiconductor device 1 in FIG. 1. The semiconductor device 1 constitutes a power MOSFET, for example. The semiconductor device 1 may be another semiconductor device including configurations illustrated in FIG. 1 and FIG. 2. For example, the semiconductor device 1 may include a transistor such as an IGBT (Insulated Gate Bipolar Transistor) or other semiconductor elements.

As illustrated in FIG. 1 and FIG. 2, the semiconductor device 1 includes a semiconductor substrate 2, an insulating film 3, an electrode 4, and an anchor member 5. The semiconductor substrate 2 is a silicon-based substrate serving as a base of the semiconductor device 1. For example, in the semiconductor substrate 2, a trench gate, a source region, a body region, and other components for constituting the power MOSFET may be formed, but components constituting the power MOSFET are not limited to them.

On the semiconductor substrate 2, the insulating film 3 is formed. For example, the insulating film 3 is referred to as an interlayer insulating film. On the insulating film 3, the electrode 4 is formed. The electrode 4 is a wire which is electrically connected with a semiconductor region in the semiconductor substrate 2. For example, the electrode 4 may be a source wire in the power MOSFET and is not limited to this.

The anchor member 5 is in contact with the insulating film 3 and the electrode 4 at an outer peripheral portion of the electrode 4, in plan view. The anchor member 5 is a member generating an anchor effect and is not limited to a particular material or a specific structure. The anchor member 5 enhances a bonding property between the insulating film 3 and the electrode 4 due to the anchor effect.

For example, the anchor member 5 may be a contact which electrically connects the semiconductor substrate 2 and the electrode 4. As one example of the contact, a source contact may be provided to electrically connect a source electrode with a source region. The anchor member 5 may be another member different from the contact, that is, a member which does not electrically connect the semiconductor substrate 2 with the electrode 4. As illustrated in FIG. 2, the anchor member 5 may be formed in such a manner as to pass through the insulating film 3 from the side of the electrode 4 and reach the side of the semiconductor substrate 2 or as not to pass through the insulating film 3, but to extend from the side of the electrode 4 to the interior of the insulating film 3.

The outer peripheral portion of the electrode 4 may include, in plan view, an outer peripheral end portion or the vicinity of the outer peripheral end portion of the electrode 4. The anchor member 5 overlaps with the outer peripheral portion of the electrode 4, in plan view. As illustrated in FIG. 1, the anchor member 5 may extend from the inner side to the outer side of the electrode 4, in plan view. As illustrated in FIG. 1, an outer end of the anchor member 5 may extend to a region outside the outer peripheral portion of the electrode 4, and may overlap with the outer peripheral portion of the electrode 4, in plan view. The anchor member 5 is not limited to any particular extending direction, any particular number, any particular shape, and the like. The anchor member 5 may extend in an outer peripheral direction of the electrode 4, in plan view. The anchor member 5 may include a plurality of anchor member portions which are spaced apart from each other.

In the embodiment, as described above, the anchor member being in contact with the insulating film and the electrode is provided at the outer peripheral portion of the electrode. Owing to the anchor effect of the anchor member, the bonding property between the insulating film and the electrode is enhanced, so that separation of the electrode from the insulating film at the outer peripheral portion of the electrode can be prevented.

### First Embodiment

Next, a first embodiment will be described. In the present embodiment, separation of a source wire is prevented by use of a source contact.

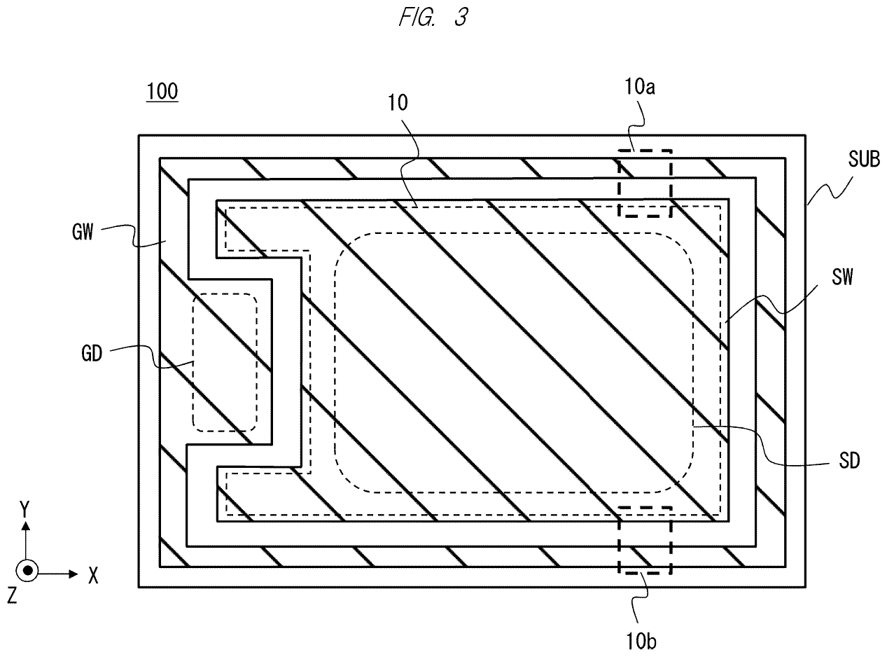

FIG. 3 is a plan view of a semiconductor chip serving as a semiconductor device 100 according to the present embodiment. For example, the semiconductor device 100 constitutes a trench gate type N-channel power MOSFET in which a field plate is connected with a gate electrode. The semiconductor device 100 may constitute not only an N-channel MOSFET, but also a P-channel MOSFET. The semiconductor device 100 may constitute a trench gate type power MOSFET which does not include a field plate. The semiconductor device 100 may constitute not only a trench gate type MOSFET, but also a transistor of any other structure.

As illustrated in FIG. 3, the semiconductor device 100 includes a semiconductor substrate SUB serving as a base of the semiconductor device 100. A gate wire GW and a source wire SW are formed on the semiconductor substrate SUB. The gate wire GW is a ring-like wire which is disposed around an end portion of the semiconductor substrate SUB. The gate wire GW is a wire (electrode) for drawing out a gate electrode in the semiconductor substrate SUB.

The source wire SW is formed to spread over the whole inner side of the gate wire GW on the semiconductor substrate SUB. The source wire SW is a wire (electrode) for drawing out a source region and a body region in the semiconductor substrate SUB.

For example, front surfaces of the gate wire GW and the source wire SW are covered with a protective film such as a polyimide film. Openings are provided in a part of the protective film, and the gate wire GW and the source wire SW which are exposed at the openings serve as a gate pad GD and a source pad SD that are external terminals, respectively.

For example, a region which overlaps with the source wire SW serves as a cell region 10. In this example, on an inner side of an outer peripheral end portion of the source wire SW, an outer peripheral end portion of the cell region 10 is present. The cell region 10 is an active region which is formed such that main elements such as a power MOSFET are operable.

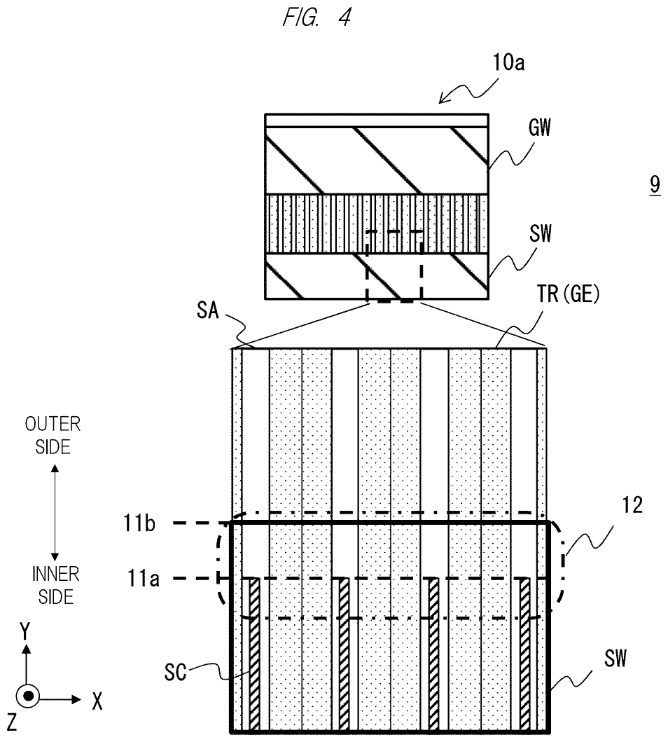

Here, a comparative example which has been studied by the inventors will be described. FIG. 4 is an enlarged plan view of a cell region end portion of a semiconductor device 9 of the comparative example. FIG. 4 is an enlarged plan view of a cell region end portion 10a in FIG. 3. FIG. 4 indicates a state in which the source wire and an interlayer insulating film are seen through. The same applies to an enlarge view of the cell region end portion in the subsequent drawings.

As illustrated in FIG. 4, in the semiconductor device 9 of the comparative example, a trench (gate trench) TR including a gate electrode GE and a source region SA extend alternately in a linear shape. For example, in FIG. 4, the Y direction (first direction) is referred to as a longitudinal direction, and the trench TR and the source region SA extend in the longitudinal direction. The longitudinal direction is also a direction perpendicular to an outer peripheral end portion 11b of the source wire SW. A source contact SC is disposed on the source region SA. The source contact SC is a contact which electrically connects the source region SA (and a body region) of the semiconductor substrate SUB with the source wire SW. The source contact SC extends in a linear shape in the longitudinal direction in such a manner as to overlap with the source region SA. It can also be said that the source contact SC extends from an inner side of the source wire SW to an outer side thereof, in plan view. In plan view, the inner side and the outer side of the source wire SW (the semiconductor substrate SUB) may be referred to simply as the inner side and the outer side. For example, a direction extending from the inner side to the outer side represents a direction extending from the inner side of the semiconductor device 100 to the cell region end portion 10a or a cell region end portion 10b in plan view of the semiconductor device 100 of FIG. 3, and also represents a positive direction or a negative direction of a Y axis.

In the comparative example, an outer end portion 11a of the source contact SC is located on an inner side of the outer peripheral end portion 11b of the source wire SW. More specifically, there is provided a margin between the outer end portion 11a of the source contact SC and the outer peripheral end portion 11b of the source wire SW. For example, in a case in which the source contact SC is formed by photolithography, even if a positional misalignment occurs in the outer end portion 11a of the source contact SC, the margin is set such that the source wire SW can completely cover the source contact SC. The source wire SW includes a barrier metal layer BM such as TiW (titanium tungsten) and an aluminum layer AL.

A reliability test was performed under high temperature on the semiconductor device 9 of the comparative example having a configuration of FIG. 4, and a defect occurred. More specifically, a threshold value Vth varied over time, and no saturation occurred. As the cause for this result, separation of the source wire SW at the cell outer peripheral portion was confirmed.

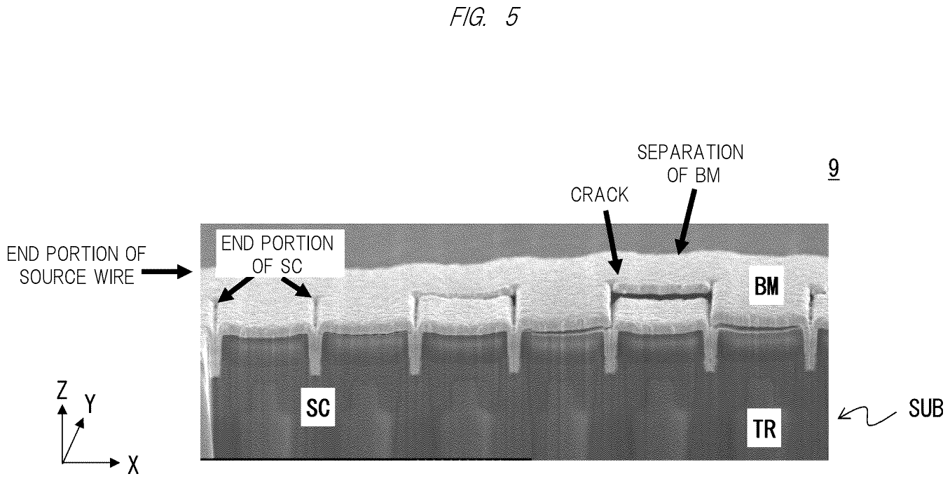

FIG. 5 indicates a result of analyzing the cell outer peripheral portion of the semiconductor device 9 of the comparative example when a reliability test was performed under high temperature. FIG. 5 is a perspective view obtained when a cross section of a region 12 of the cell outer peripheral portion of FIG. 4 is seen from the inside. FIG. 5 indicates a state in which the uppermost aluminum layer AL included in the source wire SW is removed. As in FIG. 5, as the result of the reliability test performed under high temperature, the barrier metal layer BM is separated from the semiconductor substrate SUB (the interlayer insulating film) at an end portion of the source wire SW and lifts up. The barrier metal layer BM is separated from the end portion of the source wire SW to an end portion of the source contact SC, and the barrier metal layer BM cracks at the end portion of the source contact SC.

As has been described, in the comparative example, the barrier metal layer BM (the source wire SW) may be separated from the semiconductor substrate SUB (the interlayer insulating film) under high temperature. This separation of the barrier metal layer BM is possibly caused by a stress generated due to difference in thermal expansion and thermal shrinkage properties between the barrier metal layer BM (the source wire SW) and the semiconductor substrate SUB (the interlayer insulating film) under high temperature.

To address this problem, the inventors have studied about a method for reinforcing the bonding property between the barrier metal layer BM (the source wire SW) and the semiconductor substrate SUB (the interlayer insulating film). From the analysis result of FIG. 5, it has been clear that, in a region having no source contact SC formed, the barrier metal layer BM is separated, and in a region having the source contact SC formed, the barrier metal layer BM is not separated. Consequently, the inventors have found that the source contact SC has an anchor effect of preventing separation. In view of this, in the present embodiment, the anchor effect of the source contact SC is used to allow for prevention of separation of the barrier metal layer BM (the source wire SW).

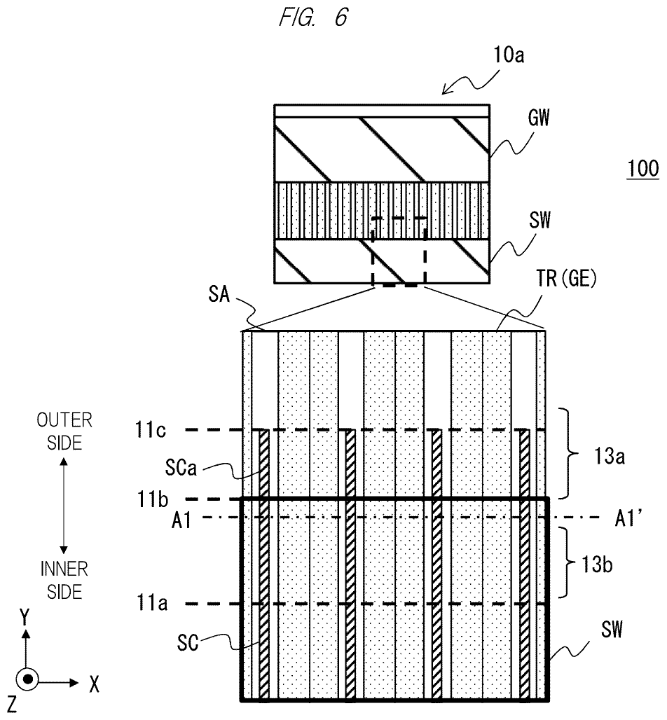

FIG. 6 is an enlarged plan view illustrating a cell region end portion of the semiconductor device 100 according to the present embodiment. FIG. 6 is an enlarged view of the cell region end portion 10a of FIG. 3. Note that, although description thereof is omitted, the cell region end portion 10b which is opposed to the cell region end portion 10a in FIG. 3 also has a configuration similar to that in FIG. 6. The same also applies to the enlarged view of the cell region end portion in the subsequent drawings.

In the present embodiment, the source contact SC having the anchor effect is disposed at the same position as or outside the end portion of the source wire SW. More specifically, the source contact SC is elongated to a region including the end portion of the source wire SW. As illustrated in FIG. 6, as in FIG. 4, in the semiconductor device 100, the trench TR including the gate electrode GE and the source region SA alternately extend in a linear shape in the longitudinal direction. In addition, the source contact SC is disposed on the source region SA. The source contact SC extends in a linear shape in the longitudinal direction, overlapping with the source region SA.

As illustrated in FIG. 6, in the present embodiment, compared to the comparative example of FIG. 4, the source contact SC is disposed in an elongated manner. More specifically, the source contact SC is elongated from the outer end portion 11a in the comparative example to an outer end portion 11c. A portion of the source contact SC from the outer end portion 11a in the comparative example to the outer end portion 11c is also referred to as an elongated portion SCa. In the example of FIG. 6, the outer end portion 11c of the source contact SC is included in a region outside the outer peripheral end portion 11b of the source wire SW. The source contact SC extends from an inner side to an outer side of the source wire SW, in plan view. At least a part of the source contact SC overlaps with the outer peripheral end portion 11b of the source wire SW, in plan view. In the example of FIG. 6, owing to the anchor effect of the source contact SC extending from the inner side to the outer side of the source wire SW, separation of the outer peripheral portion (the region including the outer peripheral end portion) of the source wire SW can be prevented reliably.

The outer end portion 11c of the source contact SC is set in a necessary range for reducing separation of the source wire SW (for example, separation at the region 12 in FIG. 4). For example, the outer end portion 11c of the source contact SC is set to an outer end portion range 13a. The outer end portion range 13a is a predetermined range from the outer peripheral end portion 11b of the source wire SW toward the outer side. Since a stress attributable to thermal expansion is varied depending on the size and the material of the source wire SW, the material of the source contact SC, and the like, the outer end portion range 13a may be set according to the size and the material of the source wire SW, the material of the source contact SC, and the like.

Note that, in the present embodiment, compared to the comparative example of FIG. 4, a margin is not set between the outer end portion 11a of the source contact SC of the comparative example and the outer peripheral end portion 11b of the source wire SW. Even though such a margin as in the comparative example is not set, for example, as long as the source contact SC is formed with a metal plug, it is possible to reduce an influence caused by etching on the source wire SW, or the like, on the source contact SC.

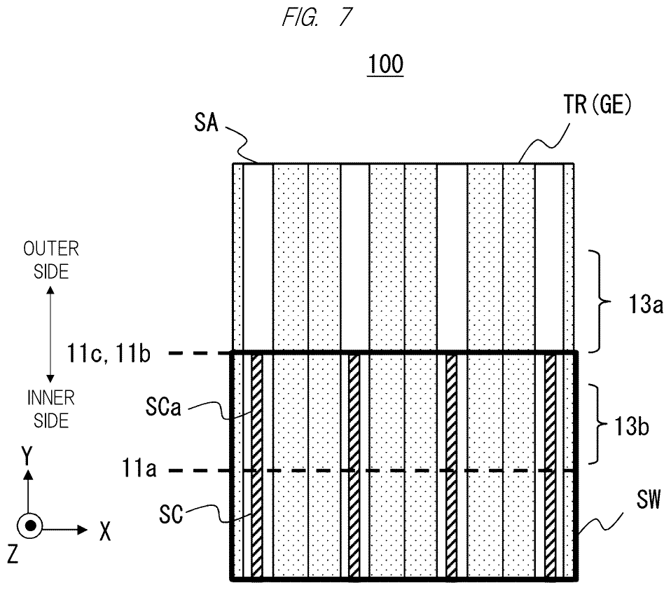

FIG. 7 is a layout example of a case in which the position of the outer end portion 11c of the source contact SC is changed. In the example of FIG. 7, the outer end portion 11c of the source contact SC is located at the same position as the outer peripheral end portion 11b of the source wire SW, in plan view. This example is not limited to a case in which the position of the outer end portion 11c of the source contact SC and the position of the outer peripheral end portion 11b of the source wire SW are the same. The outer end portion 11c of the source contact SC may be located close to the outer peripheral end portion 11b of the source wire SW or overlapped with a region including the outer peripheral end portion 11b of the source wire SW (outer peripheral portion) in plan view. Also in the case of FIG. 7, owing to the anchor effect of the source contact SC extending from the inner side of the source wire SW to the outer peripheral end portion 11b, separation of the outer peripheral portion of the source wire SW can be prevented. Note that, if separation of the source wire SW can be prevented, the outer end portion 11c of the source contact SC may be located on an inner side of the outer peripheral end portion 11b of the source wire SW.

The elongated portion SCa of the source contact SC may be integrated with the outer end portion 11a of the source contact SC of the comparative example or may be divided (spaced apart) therefrom. In other words, the source contact SC may include a first source contact portion (first anchor member portion) and a second source contact portion (second anchor member portion) which are spaced from each other. Either the first source contact portion or the second source contact portion may be the elongated portion SCa. For example, in a case in which the elongated portion SCa is divided into two portions, an inner end portion 11d of the elongated portion SCa of the source contact SC is set in an inner end portion range 13b. The inner end portion range 13b is a predetermined range from the outer end portion 11a of the source contact SC of the comparative example to a region not reaching the outer peripheral end portion 11b of the source wire SW (to such a degree that the inner end portion range 13b does not overlap with the peripheral end portion 11b). The outer end portion 11a of the source contact SC is also an end portion of the region in which the source contact SC is formed. As with the outer end portion range 13a, the inner end portion range 13b may be set depending on the size and the material of the source wire SW, the material of the source contact SC, and the like.

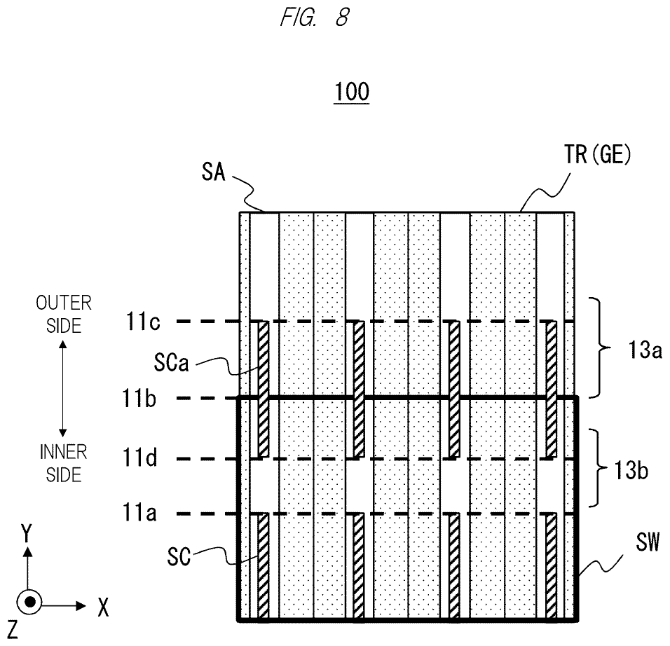

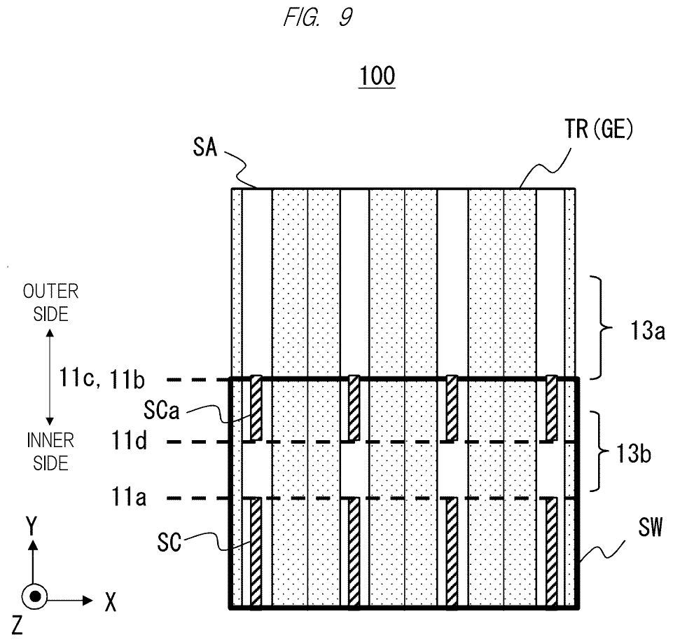

FIG. 8 and FIG. 9 are layout examples of a case in which the elongated portion SCa of the source contact SC is divided. In the example of FIG. 8, the outer end portion 11c of the elongated portion SCa of the source contact SC is located on an outer side of the outer peripheral end portion 11b of the source wire SW, as in FIG. 6. The inner end portion 11d of the elongated portion SCa of the source contact SC is located halfway between the outer peripheral end portion 11b of the source wire SW and the outer end portion 11a of the source contact SC. Also in the case of FIG. 8, owing to the anchor effect of the elongated portion SCa of the source contact SC extending from the inner side to the outer side in the vicinity of the outer peripheral end portion 11b of the source wire SW, separation of the outer peripheral portion of the source wire SW can be prevented.

In the example of FIG. 9, the outer end portion 11c of the elongated portion SCa of the source contact SC is located at the same position as the outer peripheral end portion 11b of the source wire SW, as in FIG. 7, in plan view. As in FIG. 8, the inner end portion 11d of the elongated portion SCa of the source contact SC is located halfway between the outer peripheral end portion 11b of the source wire SW and the outer end portion 11a of the source contact SC. Also in the case of FIG. 9, owing to the anchor effect of the elongated portion SCa of the source contact SC extending from the inner side to the outer peripheral end portion 11b in the vicinity of the outer peripheral end portion 11b of the source wire SW, separation of the outer peripheral portion of the source wire SW can be prevented.

Note that, in FIG. 6 to FIG. 9, patterns of a plurality of the source contacts SC are the same, but may be different from one another. Alternatively, the patterns of the plurality of the source contacts SC may be used in combination of those in FIG. 6 to FIG. 9. For example, the source contact SC having one pattern in FIG. 6 to FIG. 9 and the source contact SC having another pattern in FIG. 6 to FIG. 9 may alternately be disposed. Moreover, a pattern of any one of FIG. 6 to FIG. 9 and a pattern in the comparative example of FIG. 4 may be used in combination.

Next, a configuration of a cross section of the semiconductor device 100 according to the present embodiment will be described. FIG. 10 is a cross-sectional view of the cell region end portion 10a of the semiconductor device 100 in FIG. 6, taken along a line A1-A1′.

For example, the semiconductor substrate SUB is an N+ type silicon substrate. A drain region ND that is an N+ type semiconductor region is formed on a back surface (the lower surface) 100b side of the semiconductor substrate SUB. A drain electrode DE is formed below the N+ drain region ND of the semiconductor substrate SUB. The drain electrode DE is a metal electrode and includes, for example, Ti (titanium)/Ni (nickel)/Ag (silver), or the like in the order closer to the semiconductor substrate SUB.

A drift region NV that is an N− type semiconductor region is formed on a side of a substrate front surface (upper surface) 100a of the N+ drain region ND. The N− type drift region NV is a silicon epitaxial region. A body region PB that is a P− type semiconductor region is formed on the N− type drift region NV. The P− body region PB is a channel region (injection layer). A source region SA that is an N+ type semiconductor region is formed on the side of the substrate front surface (upper surface) 100a of the P− body region PB.

A trench TR is formed on the side of the substrate front surface 100a of the semiconductor substrate SUB. The trench TR is a gate trench for a gate electrode. the trench TR is formed so as to pass through the N+ source region SA and the P− body region PB from the substrate front surface 100a and reach the interior of the N− drift region NV. A field plate electrode FE is formed on a lower side (bottom side) of the interior of the trench TR. The field plate electrode FE is an electrode which is connected with a gate. For example, the field plate electrode FE is an N+ polysilicon field plate electrode. A lower portion and a side surface portion of the field plate electrode FE is surrounded by the field plate peripheral insulating film FF. For example, the field plate peripheral insulating film FF is a silicon oxide film.

A gate electrode GE is formed above the field plate electrode FE in the trench TR, with a field plate-gate interlayer insulating film FG therebetween. For example, the gate electrode GE is an N+ polysilicon trench gate electrode. A side surface portion of the gate electrode GE is surrounded by a gate insulating film GF. For example, the field plate-gate interlayer insulating film FG and the gate insulating film GF are silicon oxide films. The field plate peripheral insulating film FF and the gate insulating film GF may be integrally formed.

On the side of the front surface 100a of the semiconductor substrate SUB, an interlayer insulating film IL is formed in such a manner as to cover the gate electrode GE and the source region SA. A contact hole CH for the source contact SC is formed in the interlayer insulating film IL. The contact hole CH is formed so as to pass through the interlayer insulating film IL and the N+ source region SA from an upper side (the front surface side) of the interlayer insulating film IL and reach a P+ body contact region PC inside the P− body region PB. On an inner surface of the contact hole CH, a source contact SC is buried. The source contact SC is a metal plug and includes, for example, Ti (titanium)/TiN (titanium nitride)/W (tungsten), or the like in the order closer to the semiconductor substrate SUB. The source contact SC has an upper portion being in contact with the source wire SW (a barrier metal layer BM) and passes through the interlayer insulating film IL and reaches the semiconductor substrate SUB. Owing to such an anchor structure that an anchor is driven into the interlayer insulating film IL from the source wire SW side, an anchor effect of enhancing a bonding property between the source wire SW and the interlayer insulating film IL is generated. The source contact SC is an anchor member having an anchor function of generating the anchor effect and a contact function.

The source wire SW is formed on an upper surface of the interlayer insulating film IL. In this example, as the source wire SW, the barrier metal layer and an aluminum layer AL are layered. More specifically, the barrier metal layer BM is formed on the upper surface of the interlayer insulating film IL. The barrier metal layer BM is, for example, a metal film such as TiW.

Moreover, the aluminum layer AL that is relatively thick is formed on an upper surface of the barrier metal layer BM.

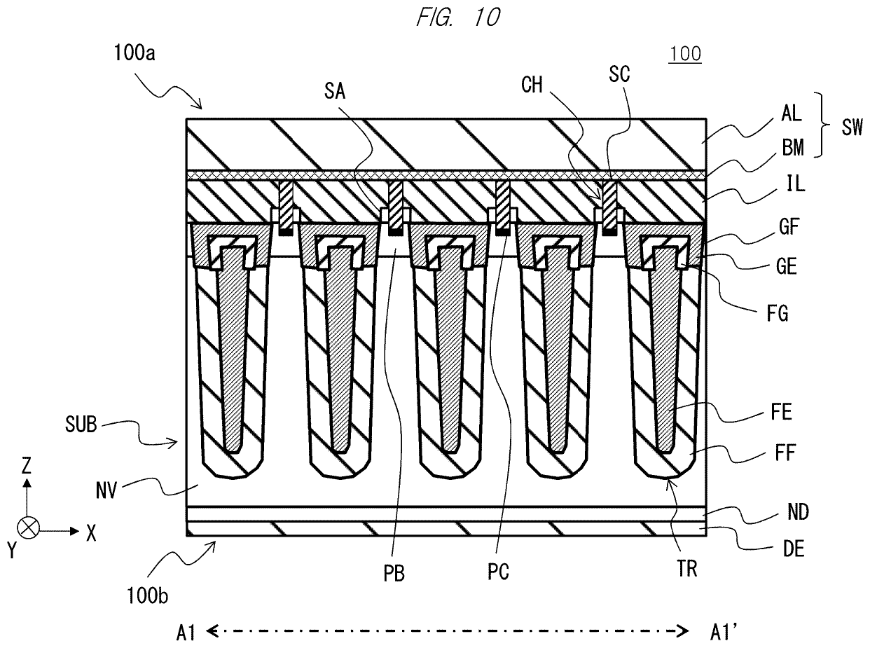

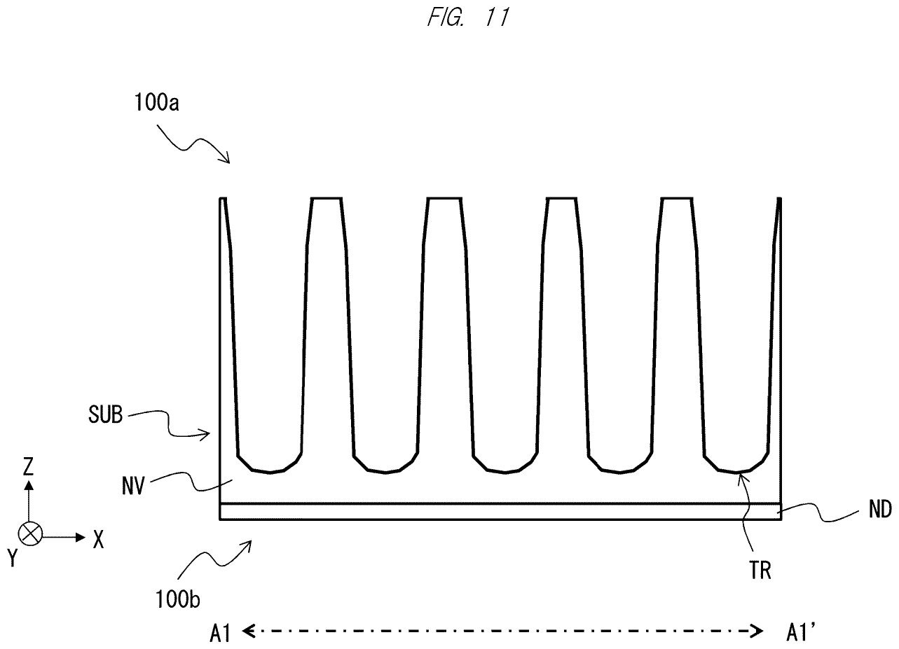

Next, a method of manufacturing the semiconductor device 100 according to the present embodiment will be described. FIG. 11 to FIG. 17 illustrate the cross section taken along the line A1-A1′ in FIG. 6, as in FIG. 10.

As illustrated in FIG. 11, first, the semiconductor substrate SUB having the N− drift region NV that is the N− type semiconductor region is prepared, and the trench TR is formed in the N− drift region NV. For example, a silicon layer is promoted to grow by being doped with P (phosphorus) through the epitaxial growth, so that the N− drift region NV is formed on the N+ type silicon substrate (N+ drain region ND). Next, for example, the insulating film including silicon oxide film is formed on the semiconductor substrate SUB by the CVD (Chemical Vapor Deposition), and a resist pattern having an opening is formed on the insulating film by photolithography. Dry etching is performed on the insulating film and the N− drift region NV which are exposed at the opening, with the resist pattern as a mask, and accordingly, the trench TR is formed in the N− drift region NV. Then, the resist pattern is removed by ashing, and the insulating film is removed by wet etching.

Next, as illustrated in FIG. 12, the field plate electrode FE is formed in the trench TR with the field plate peripheral insulating film FF interposed therebetween. First, for example, the field plate peripheral insulating film FF including a silicon oxide film is formed on the semiconductor substrate SUB including the interior of the trench TR by thermal oxidation. Next, for example, a heavily P-doped polysilicon layer doped with N type impurities is formed on the semiconductor substrate SUB by the CVD in order to bury the trench TR with the field plate peripheral insulating film FF interposed therebetween. Subsequently, for example, by the CMP or dry etching, the heavily P-doped polysilicon layer positioned outside the trench TR and the heavily P-doped polysilicon layer positioned on the upper side of the interior of the trench TR are etched back to form the field plate electrode FE. Then, for example, wet etching is performed to remove the field plate peripheral insulating film FF to such an extent that the upper end of the field plate electrode FE and a silicon side wall of the trench TR positioned higher than the field plate electrode FE are exposed.

Next, as illustrated in FIG. 13, the gate electrode GE is formed above the field plate electrode FE in the trench TR. First, for example, the gate insulating film GF including a silicon oxide film is formed on the semiconductor substrate SUB including the interior of the trench TR formed with the field plate electrode FE by thermal oxidation. Concurrently with the gate insulating film GF, the field plate-gate interlayer insulating film FG is formed. Subsequently, for example, the heavily P-doped polysilicon layer doped with N type impurities is formed on the semiconductor substrate SUB through the gate insulating film GF by the CVD in such a manner as to bury the trench TR. Then, for example, by the CMP or dry etching, the heavily P-doped polysilicon layer positioned outside the trench TR is etched back to form the gate electrode GE.

Next, as illustrated in FIG. 14, the P− body region PB is formed on a front surface of the N− drift region NV, and the N+ source region SA is formed on a front surface of the body region PB. First, by photolithography and ion implantation, B (boron) or the like is doped into the front surface of the N− drift region NV, so that the P− body region PB is formed. Subsequently, by photolithography and ion implantation, As (arsenic) or the like is doped into the front surface of the P− body region PB, so that the N+ source region SA is formed.

Next, as illustrated in FIG. 15, the interlayer insulating film IL is formed on the semiconductor substrate SUB, the contact hole CH is formed in the interlayer insulating film IL, and the P+ body contact region PC is formed in the P− body region PB. First, for example, the interlayer insulating film IL including the silicon oxide film is formed on the semiconductor substrate SUB by the CVD so as to cover the gate electrode GE and the source region SA. Subsequently, the resist on the interlayer insulating film IL is patterned by photolithography so as to obtain the pattern of the source contact SC described above. Moreover, by dry etching, from each opening of the resist pattern, the contact hole CH passing through the interlayer insulating film IL and the N+ source region SA is formed. A bottom portion of the contact hole CH is formed to be located in the P-body region PB. Moreover, the resist pattern is removed by ashing or wet etching. Then, at the bottom portion of the contact hole CH, ion implantation of B (boron) is performed in the P-body region PB, so that the P+ body contact region PC having an impurity concentration higher than that of the P− body region PB is formed.

Next, as illustrated in FIG. 16, the source contact SC is formed in the contact hole CH. First, for example, by sputtering or the CVD, a metal film such as Ti/TiN is formed on the entire inner surface of the contact hole CH extending from the interlayer insulating film IL to the P+ body contact region PC. Subsequently, for example, so as to bury the contact hole CH, the metal plug such as W is formed on the metal film such as Ti/TiN, by sputtering or the CVD, and the metals (Ti/TiN and W) included in a front layer of the interlayer insulating film IL are removed by dry etching, resulting in formation of the source contact SC.

Next, as illustrated in FIG. 17, the source wire SW is formed on the source contact SC and the interlayer insulating film IL. First, for example, by sputtering or the CVD, the barrier metal layer BM including TiW is formed on the entire surface of the source contact SC and the interlayer insulating film IL. Subsequently, for example, by sputtering or the CVD, the aluminum layer AL is formed on the entire surface of the barrier metal layer BM. Moreover, the source wire SW including the barrier metal layer BM and the aluminum layer AL is patterned by photolithography.

As described above, in the present embodiment, the source contact is disposed to be elongated to a region including the outer peripheral end portion of the source wire. The anchor effect of this source contact can prevent separation of the source wire at the outer peripheral end portion of the source wire. Use of the source contact electrically connecting the source region and the source wire enables separation of the source wire to be prevented efficiently.

### Second Embodiment

Next, a second embodiment will be described. In the present embodiment, a narrow contact different from the source contact is used to prevent separation of the source wire.

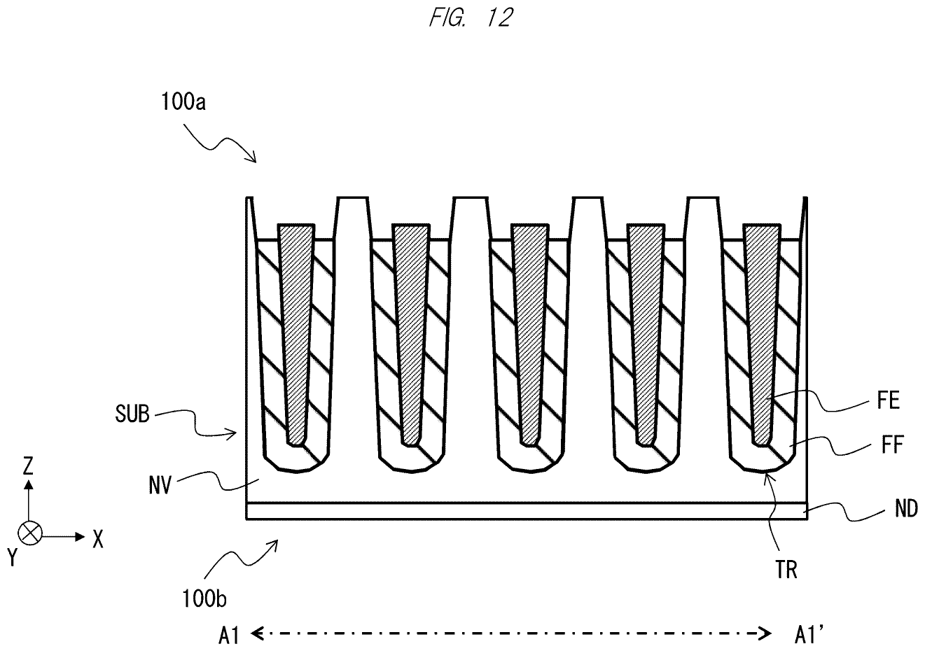

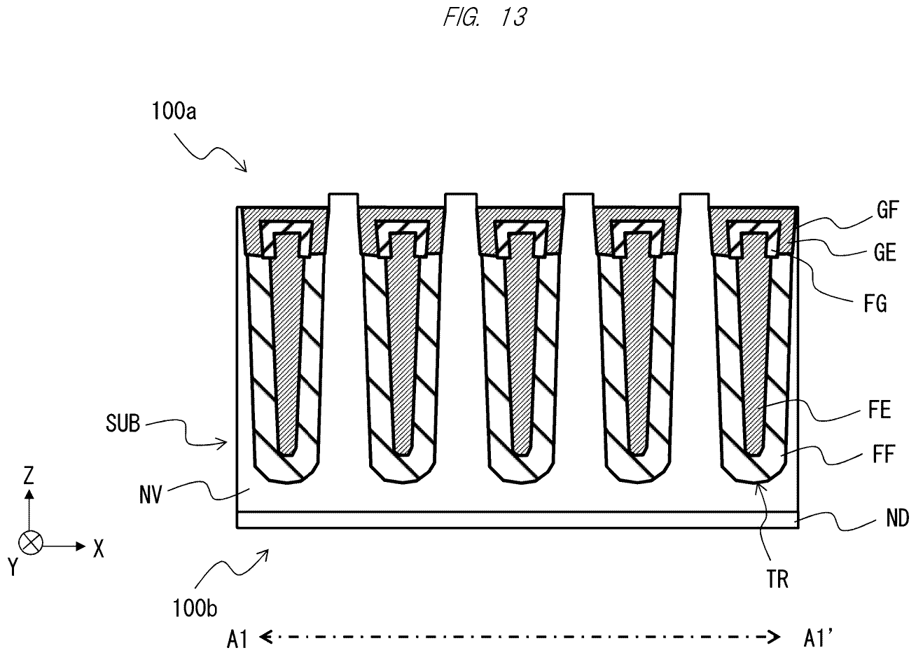

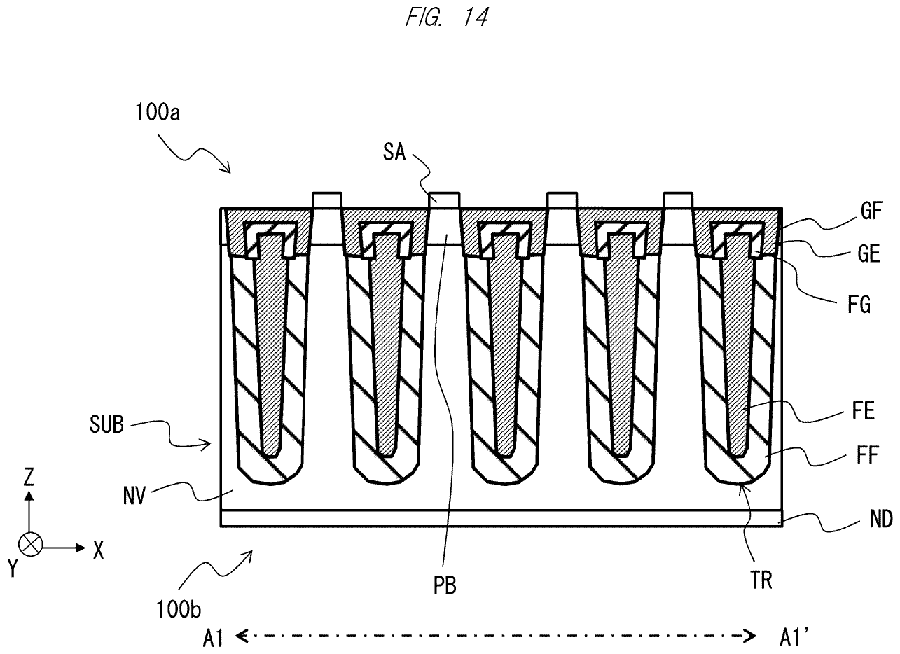

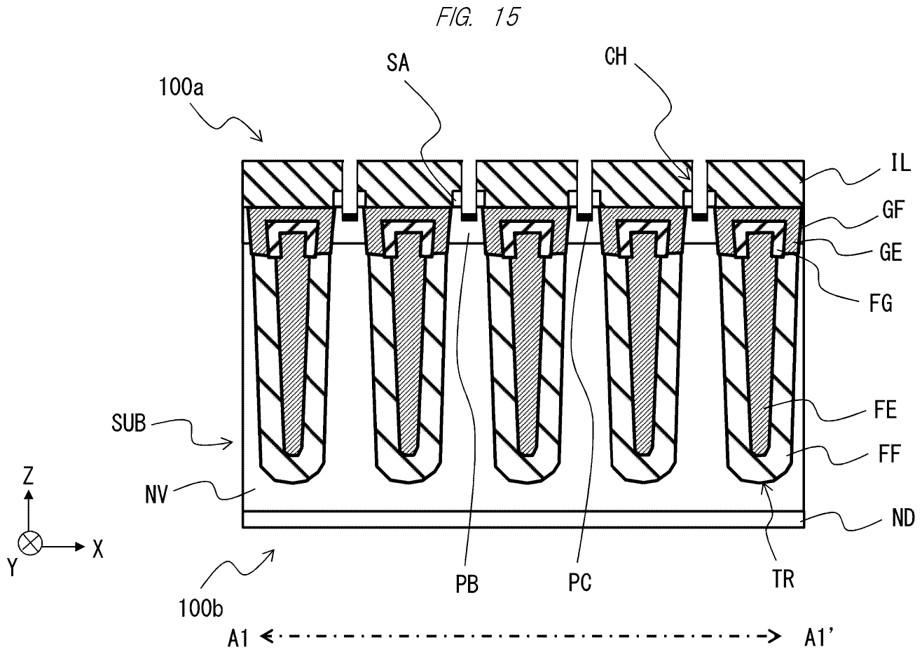

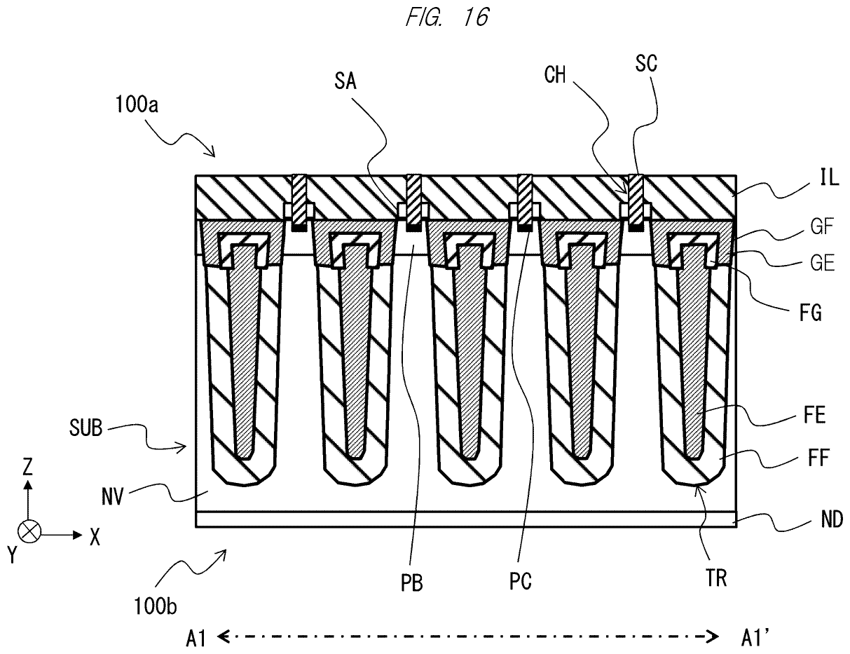

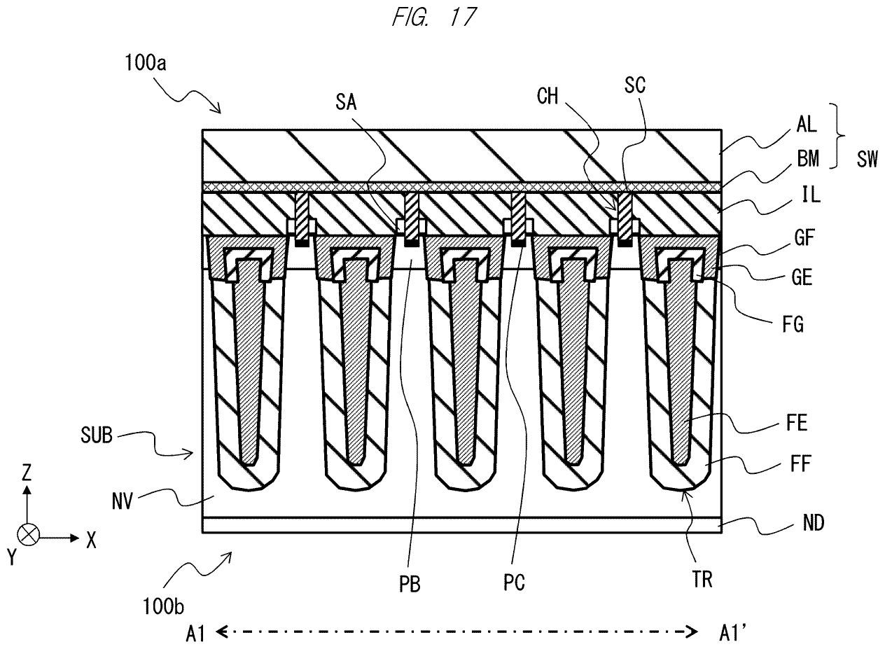

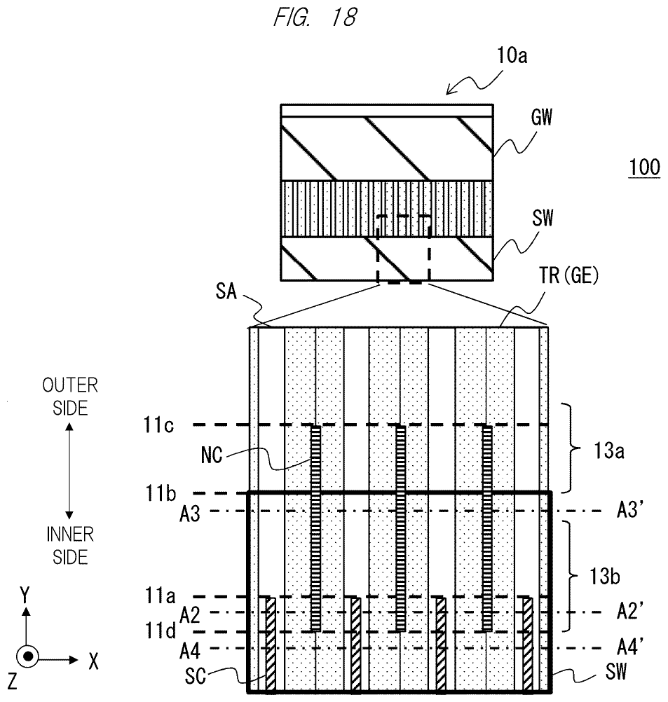

FIG. 18 is an enlarged plan view of the cell region end portion of the semiconductor device 100 according to the present embodiment. FIG. 18 is an enlarged plan view of the cell region end portion 10a in FIG. 3. FIG. 19 is a cross-sectional view taken along a line A2-A2′ in FIG. 18. FIG. 20 is a cross-sectional view taken along a line A3-A3′ in FIG. 18.

In the present embodiment, a narrow contact NC which is a member different from the source contact SC is disposed at the same position as or outside the end portion of the source wire SW. Note that the configurations other than that of the narrow contact NC are similar to those in the first embodiment.

As illustrated in FIG. 19 and FIG. 20, the narrow contact NC is shallower than the source contact SC. The narrow contact NC does not pass through the interlayer insulating film IL, and the bottom portion of the narrow contact NC is located at the interior of the interlayer insulating film IL. As long as the narrow contact NC is not in contact with the gate electrode GE, the narrow contact NC is not limited to any particular depth. The interlayer insulating film IL has a contact hole CH2 for the narrow contact NC formed therein. The contact hole CH2 is formed so as to extend from the upper side (the front surface side) of the interlayer insulating film IL to the interior of the interlayer insulating film IL. On an inner surface of the contact hole CH2, the narrow contact NC is buried. For example, a width (diameter) of the narrow contact NC is the same as that of the source contact SC, but it may be any width different from that of the source contact SC.

The narrow contact NC has an upper portion being in contact with the source wire SW (the barrier metal layer BM) and the bottom portion reaching the interior of the interlayer insulating film IL. With such an anchor structure that an anchor is driven into the interlayer insulating film IL from the source wire SW side, as with the source contact SC, the anchor effect of enhancing the bonding property between the source wire SW and the interlayer insulating film IL is generated.

Since the bottom portion of the narrow contact NC is located in the interior of the interlayer insulating film IL, the narrow contact NC does not establish electrical connection between the source wire SW and the gate electrode GE of the semiconductor substrate SUB, and the like. The narrow contact NC does not affect the characteristics of the power MOSFET, so that the narrow contact NC may be disposed at a freely selected position. The narrow contact NC is an anchor member which has the anchor function of generating the anchor effect and has no contact function. For example, as in the source contact SC, the narrow contact NC may be a metal plug such as Ti/TiN/W. The narrow contact NC may be a metal film such as TiW, as with the barrier metal layer BM. The narrow contact NC may include any other materials, as long as it can generate the anchor effect.

As illustrated in FIG. 18, for example, as in the source contact SC, the narrow contact NC extends in a linear shape in the longitudinal direction, and is disposed to be lined up in parallel to the source contact SC. For example, the narrow contact NC is disposed so as to overlap with the gate electrode GE between adjacent ones of the source contacts SC, that is, at the center of each of the trenches TR. It can also be said that the narrow contact NC extends from the inner side of the source wire SW to the outer side thereof, in plan view, as in the source contact SC.

In the example of FIG. 18, the outer end portion 11c of the narrow contact NC is included in a region outside the outer peripheral end portion 11b of the source wire SW, as in the first embodiment of FIG. 6. The inner end portion 11d of the narrow contact NC is included in a region on the inner side of the outer end portion 11a of the source contact SC (as in the comparative example). More specifically, the region of the inner end portion 11d of the narrow contact NC overlaps with the region of the outer end portion 11a of the source contact SC. At least a part of the narrow contact NC overlaps with the outer peripheral end portion lib of the source wire SW, in plan view. In the example of FIG. 18, as in the first embodiment, owing to the anchor effect of the narrow contact NC extending from the inner side of the source wire SW to the outer side thereof, it is possible to reliably prevent separation of the outer peripheral portion of the source wire SW.

The outer end portion 11c and the inner end portion 11d of the narrow contact NC are set in a range necessary for preventing separation of the source wire SW (for example, the separation at the region 12 in FIG. 4). For example, the outer end portion 11c of the narrow contact NC is set to the outer end portion range 13a. The outer end portion range 13a is a predetermined range from the outer peripheral end portion lib of the source wire SW toward the outer side. The inner end portion 11d of the narrow contact NC is set to the inner end portion range 13b. The inner end portion range 13b is a predetermined range from the region on the inner side of the outer end portion 11a of the source contact SC to a region not reaching the outer peripheral end portion 11b of the source wire SW (to such a degree that the inner end portion range 13b does not overlap with the outer peripheral end portion 11b). As in the first embodiment, the outer end portion range 13a and the inner end portion range 13b may be set depending on the size and the material of the source wire SW, the material of the narrow contact NC, and the like.

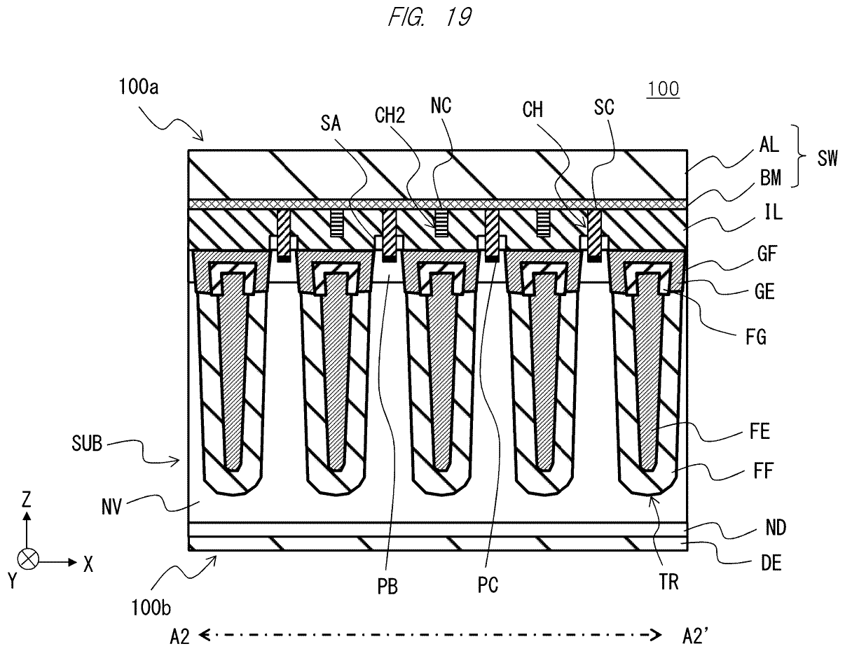

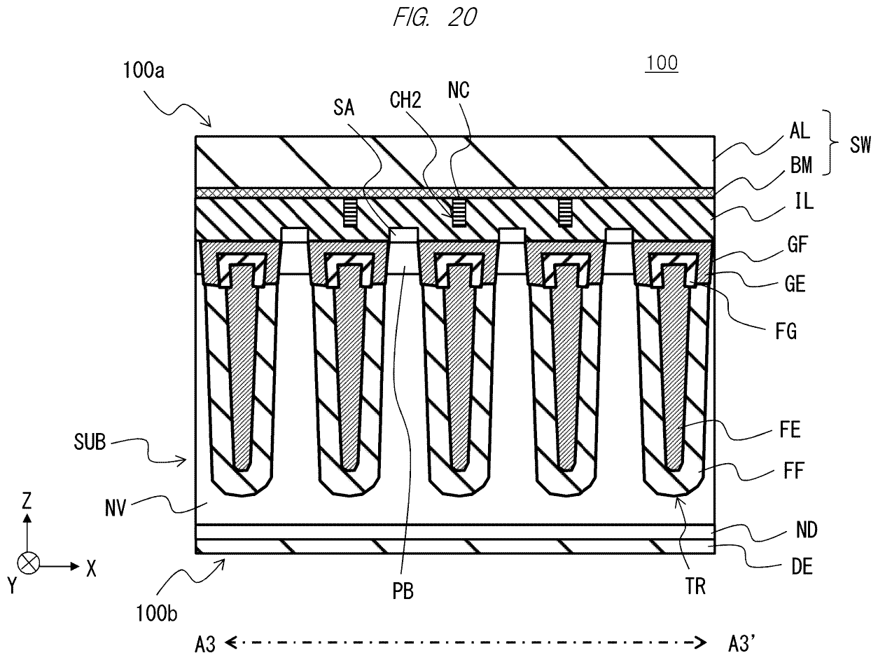

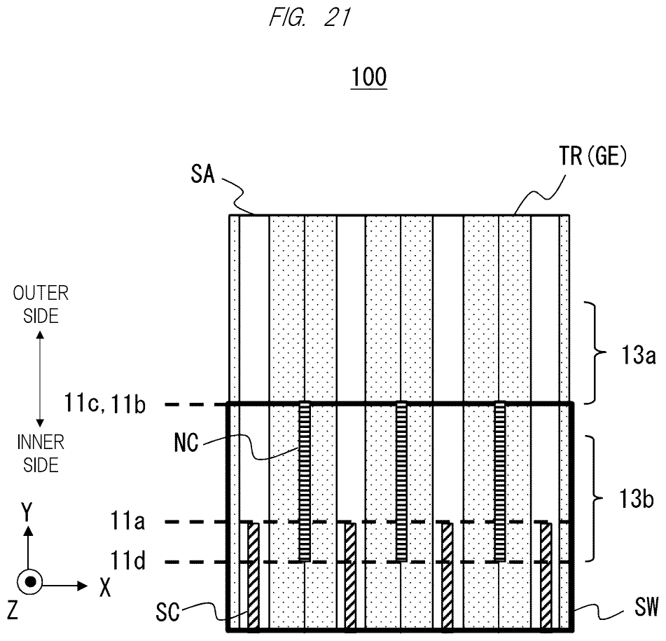

FIG. 21 is a layout example of a case in which the position of the outer end portion 11c of the narrow contact NC is changed. In the example of FIG. 21, as in the first embodiment in FIG. 7, the outer end portion 11c of the narrow contact NC is located at the same position as the outer peripheral end portion lib of the source wire SW, in plan view. Specifically, the outer end portion 11c of the narrow contact NC may be in the vicinity of the outer peripheral end portion lib of the source wire SW or may overlap with the region including the outer peripheral end portion lib of the source wire SW (the outer peripheral portion), in plan view. The inner end portion 11d of the narrow contact NC is located on the inner side of the outer end portion 11a of the source contact SC, as in FIG. 18. Also in the case of FIG. 21, owing to the anchor effect of the narrow contact NC extending from the inner side of the source wire SW to the outer peripheral end portion lib, separation of the outer peripheral portion of the source wire SW can be prevented. Note that, if separation of the source wire SW can be prevented, the outer end portion 11c of the narrow contact NC may be located on the inner side of the outer peripheral end portion lib of the source wire SW.

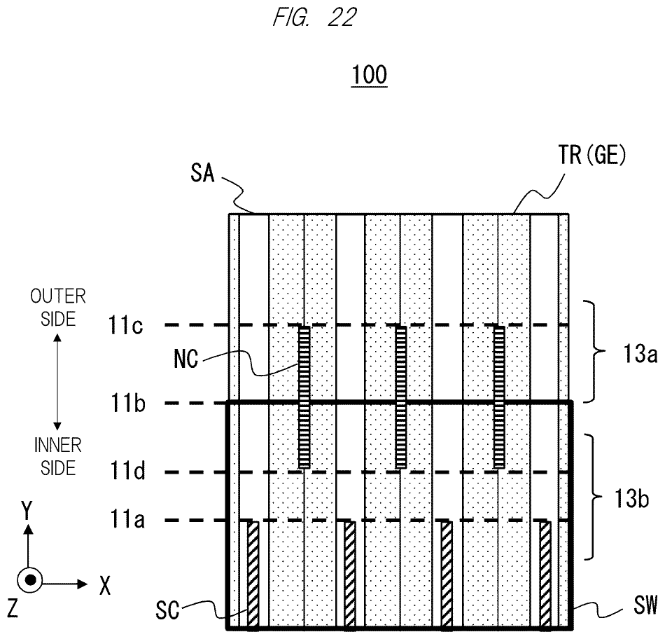

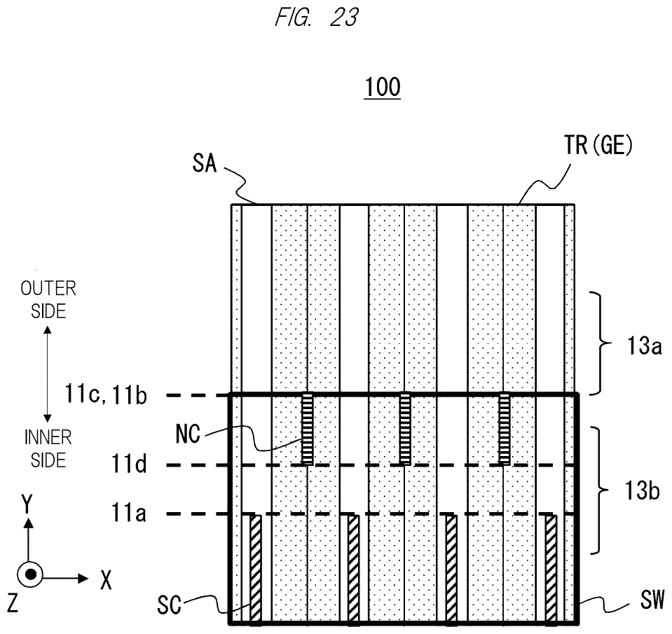

FIG. 22 and FIG. 23 are layout examples of a case in which the position of the inner end portion 11d of the narrow contact NC is changed. In the example of FIG. 22, the outer end portion 11c of the narrow contact NC is located on the outer side of the outer peripheral end portion lib of the source wire SW, as in FIG. 18. The inner end portion 11d of the narrow contact NC is located halfway between the outer peripheral end portion lib of the source wire SW and the outer end portion 11a of the source contact SC, as in FIG. 8 of the first embodiment. Specifically, the region of inner end portion 11d of the narrow contact NC does not overlap with the region of the outer end portion 11a of the source contact SC. Also in the case of FIG. 22, owing to the anchor effect of the narrow contact NC extending from the inner side to the outer side at the periphery of the outer peripheral end portion 11b of the source wire SW, separation of the outer peripheral portion of the source wire SW can be prevented.

In the example of FIG. 23, as in FIG. 21, the outer end portion 11c of the narrow contact NC is located at the same position as that of the outer peripheral end portion lib of the source wire SW in plan view. The inner end portion 11d of the narrow contact NC is located halfway between the outer peripheral end portion lib of the source wire SW and the outer end portion 11a of the source contact SC, as in FIG. 22. Also in the case of FIG. 23, the anchor effect of the narrow contact NC extending from the inner side to the outer peripheral end portion 11b of the source wire SW at the periphery of the outer peripheral end portion 11b of the source wire SW, separation of the outer peripheral portion of the source wire SW can be prevented.

Note that the narrow contact NC may be divided, as in FIG. 8 and FIG. 9 of the first embodiment. Specifically, the narrow contact NC may include a first narrow contact portion (first anchor member portion) and a second narrow contact portion (second anchor member portion) which are spaced apart. In addition, the pattern of the source contact SC according to the first embodiment may be used in combination with the pattern of the narrow contact NC according to the present embodiment. For example, not only the source contact SC having any of the patterns in FIG. 6 to FIG. 9 of the first embodiment, but also the narrow contact NC having any of the patterns in FIG. 18 and FIG. 21 to FIG. 23 may be additionally disposed. As a result, it is possible to prevent separation of the outer peripheral portion of the source wire SW more reliably.

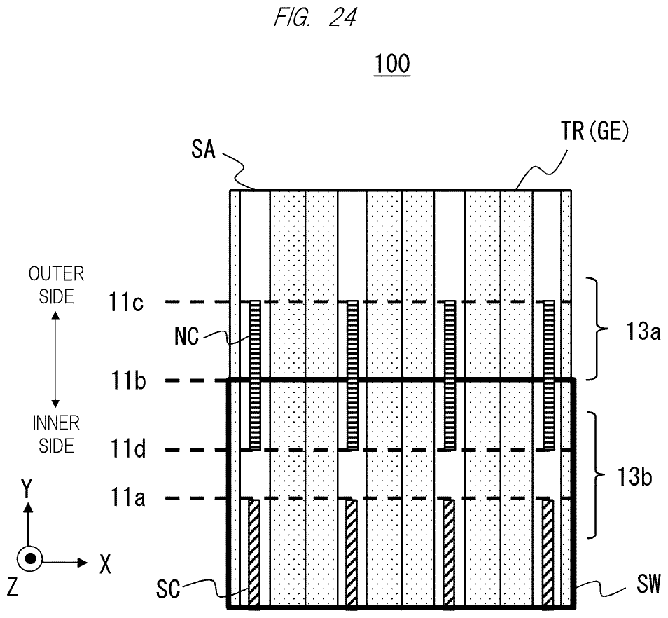

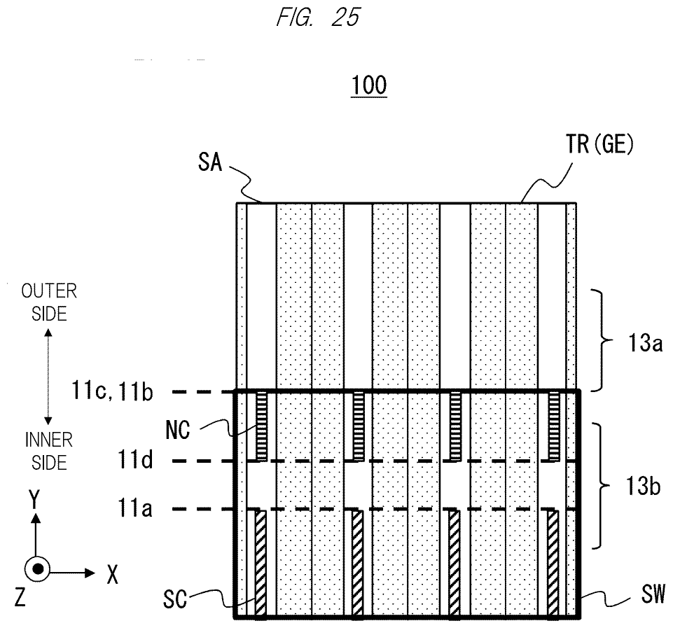

FIG. 24 and FIG. 25 are layout examples of a case in which the position of the narrow contact NC in the X direction is changed. In the examples of FIG. 24 and FIG. 25, the narrow contact NC is disposed in the source region SA, in other words, in an extension of the source contact SC. In the example of FIG. 24, the positions of the outer end portion 11c and the inner end portion 11d of the narrow contact NC are the same as those in FIG. 22. The position of the narrow contact NC in FIG. 24 is the same as that of the elongated portion SCa in FIG. 8 of the first embodiment. In the example of FIG. 25, the positions of the outer end portion 11c and the inner end portion 11d of the narrow contact NC are disposed at the same positions as those in FIG. 23. The position of the narrow contact NC in FIG. 25 is the same as that of the elongated portion SCa in FIG. 9 of the first embodiment. Even in these cases, as in FIG. 22 and FIG. 23, it is possible to prevent separation of the outer peripheral portion of the source wire SW.

Note that, from FIG. 18 and FIG. 21 to FIG. 25, the patterns of a plurality of the narrow contacts NC are the same, but may be different from one another. The patterns in FIG. 18 and FIG. 21 to FIG. 25 may be used in combination. For example, the narrow contact NC having one of the patterns in FIG. 18 and FIG. 21 to FIG. 23 and the narrow contact NC having another pattern in FIG. 18 and FIG. 21 to FIG. 23 may be disposed alternately. For example, after the narrow contact NC having any one of the patterns in FIG. 18 and FIG. 21 to FIG. 23 is disposed, the narrow contact NC having the pattern in either FIG. 24 or FIG. 25 may be additionally disposed.

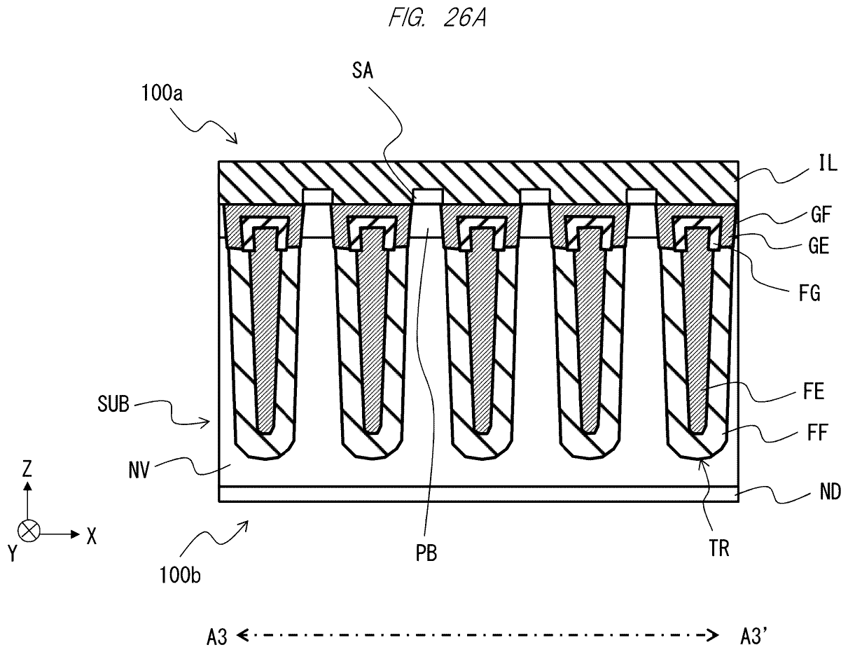

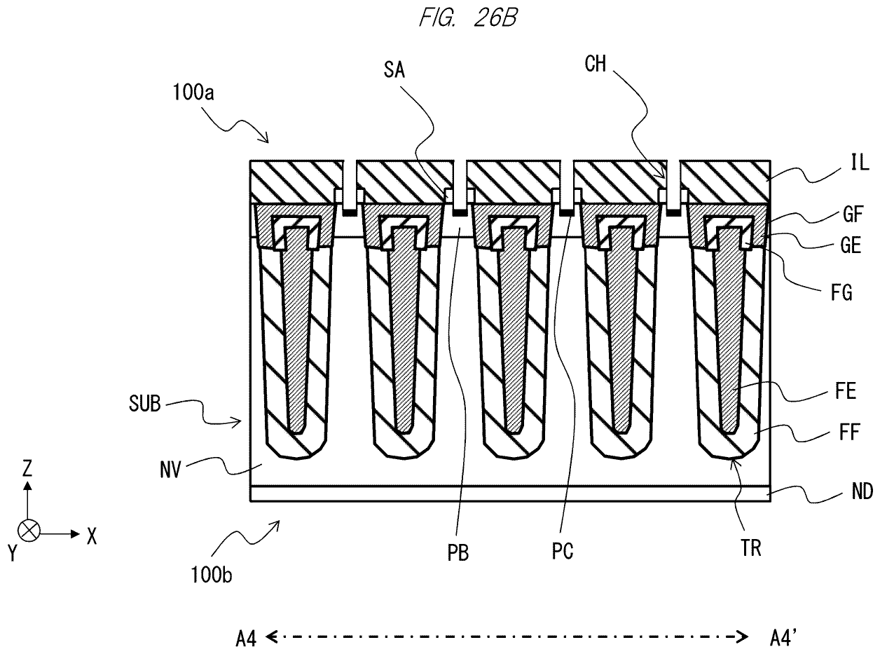

Next, an example of a method of manufacturing the semiconductor device 100 according to the present embodiment will be described. In this example, before the source contact SC is formed after the contact hole for the source contact SC is opened, the contact hole for the narrow contact NC is formed, and then, the source contact SC and the narrow contact NC are formed at the same time. FIG. 26A to FIG. 30A each illustrate a cross section taken along a line A3-A3′ in FIG. 18 and a cross section of a region where the narrow contact NC is to be formed. FIG. 26B to FIG. 30B each illustrate a cross section taken along a line A4-A4′ in FIG. 18 and a cross section of a region where the source contact SC is to be formed.

First, after the same processes as those in FIG. 11 to FIG. 14 of the first embodiment are carried out, the manufacturing process goes to the processes in FIG. 26A and FIG. 26B. FIG. 26A and FIG. 26B correspond to the process of FIG. 15 of the first embodiment. In other words, as indicated in FIG. 26A and FIG. 26B, as in FIG. 15, the interlayer insulating film IL is formed on the semiconductor substrate SUB. Next, as illustrated in FIG. 26B, in the region where the source contact SC is to be formed, the contact hole CH for the source contact SC passing through the interlayer insulating film IL and the N+ source region SA and reaching the interior of the P− body region PB is formed. Moreover, the P+ body contact region PC is formed through the contact hole CH, in the P-body region PB. At this time, as illustrated in FIG. 26A, in the region where the narrow contact NC is to be formed, the interlayer insulating film IL is formed on the semiconductor substrate SUB.

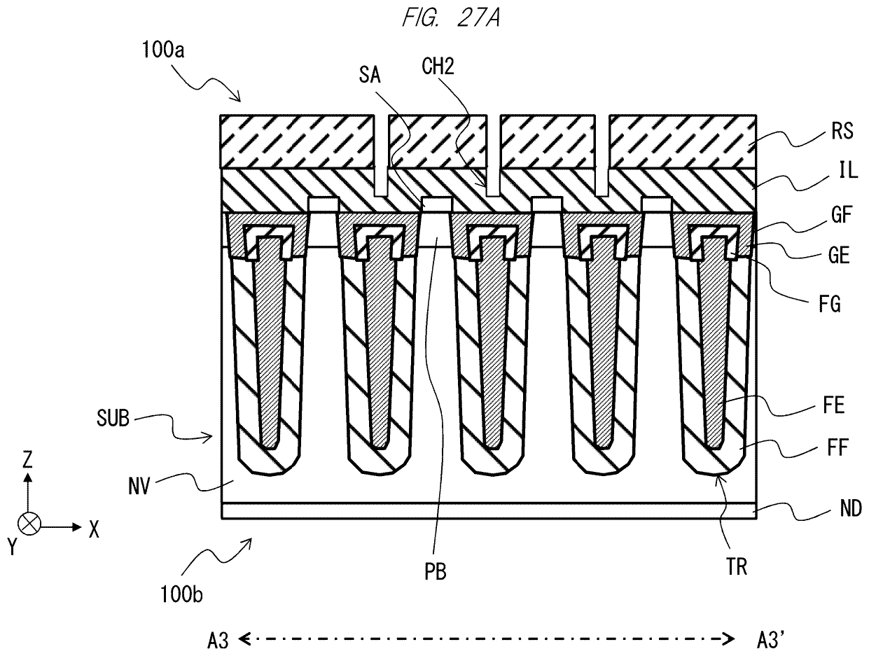

Next, as illustrated in FIG. 27A and FIG. 27B, a resist RS is formed on the interlayer insulating film IL, and a resist pattern for the narrow contact NC is formed. Specifically, as illustrated in FIG. 27A, in the region where the narrow contact NC is to be formed, in order to achieve the pattern of the narrow contact NC described above, the resist RS is patterned on the interlayer insulating film IL by photolithography. Moreover, by dry etching, the interlayer insulating film IL is removed from each opening of the pattern of the resist RS at a fixed depth, resulting in formation of the contact hole CH2 for the narrow contact NC. A bottom portion of the contact hole CH2 is formed so as to be located in the interlayer insulating film IL. At this time, as illustrated in FIG. 27B, in the region where the source contact SC is to be formed, the resist RS is formed in the contact hole CH for the source contact SC and on the interlayer insulating film IL.

Next, as illustrated in FIG. 28A and FIG. 28B, by ashing or wet etching, the pattern of the resist RS is removed. As illustrated in FIG. 28A, in the region where the narrow contact NC is to be formed, the patterns of the resist RS in the contact hole CH2 for the narrow contact NC and the resist RS on the interlayer insulating film IL are removed. At the same time, as illustrated in FIG. 28B, in the region where the source contact SC is to be formed, the patterns of the resist RS in the contact hole CH for the source contact SC and the resist RS on the interlayer insulating film IL are removed.

Next, as illustrated in FIG. 29A and FIG. 29B, the source contact SC and the narrow contact NC are formed at the same time. In this example, the source contact SC and the narrow contact NC include the same materials. A method of forming the contact is the same as that of FIG. 16 of the first embodiment. Specifically, as illustrated in FIG. 29A and FIG. 29B, by sputtering or the CVD, in the region where the source contact SC is to be formed, on the entire region of the inner surface of the contact hole CH extending from the interlayer insulating film IL to the P+ body contact region PC, a metal film such as Ti/TiN is formed, and at the same time, also in the region where the narrow contact NC is to be formed, on the entire region of the inner surface of the contact hole CH2 reaching the interior of the interlayer insulating film IL, a metal film such as Ti/TiN is formed. Subsequently, by sputtering or the CVD, in the region where the source contact SC is to be formed, so as to bury the contact hole CH, a metal plug such as W is formed on the metal film such as Ti/TiN, and by dry etching, the metals (Ti/TiN and W) in the front layer of the interlayer insulating film IL are removed to form the source contact SC. At the same time, also in the region where the narrow contact NC is to be formed, so as to bury the contact hole CH2, a metal plug such as W is formed on the metal film such as Ti/TiN to form the narrow contact NC.

Next, as illustrated in FIG. 30A and FIG. 30B, the source wire SW is formed. The method of forming the source wire SW is the same as that of FIG. 17 of the first embodiment. Specifically, as illustrated in FIG. 30A and FIG. 30B, by sputtering or the CVD, in the region where the source contact SC is formed, the barrier metal layer BM including TiW is formed on the entire surfaces of the source contact SC and the interlayer insulating film IL. At the same time, also in the region where the narrow contact NC is formed, the barrier metal layer BM such as TiW is formed on the entire surfaces of the narrow contact NC and the interlayer insulating film IL. Then, by sputtering or the CVD, in the regions where the source contact SC is formed and the narrow contact NC is formed, an aluminum layer AL is formed on the entire surface of the barrier metal layer BM.

Next, another example of the method of manufacturing the semiconductor device 100 according to the present embodiment will be described. In this example, after the source contact SC is formed, the narrow contact is formed in a process different from the source contact SC. FIG. 31A to FIG. 34A each illustrate a cross section taken along a line A3-A3′ in FIG. 18 and a cross section of the region where the narrow contact NC is to be formed. FIG. 31B to FIG. 34B each illustrate a cross section taken along a line A4-A4′ in FIG. 18 and a cross section of the region where the source contact SC is to be formed.

First, as in the example of the manufacturing method described above, the processes up to FIG. 26A and FIG. 26B are carried out. Specifically, the interlayer insulating film IL is formed on the semiconductor substrate SUB, and in the region where the source contact SC is to be formed, the contact hole CH for the source contact SC is formed.

Next, as illustrated in FIG. 31A and FIG. 31B, the source contact SC is formed. The method of forming the contact is the same as that in FIG. 16 of the first embodiment. Specifically, as illustrated in FIG. 31B, in the region where the source contact SC is to be formed, by sputtering or the CVD, a metal film such as Ti/TiN is formed on the entire region of the inner surface of the contact hole CH extending from the interlayer insulating film IL to the P+ body contact region PC. Then, by sputtering or the CVD, a metal plug such as W is formed on the metal film such as Ti/TiN so as to bury the contact hole CH, and by dry etching, the metals (Ti/TiN and W) in the front layer of the interlayer insulating film IL are removed to form the source contact SC. At this time, as illustrated in FIG. 31A, in the region where the narrow contact NC is to be formed, the interlayer insulating film IL remains on the semiconductor substrate SUB without any change.

Subsequently, as illustrated in FIG. 32A and FIG. 32B, the resist RS is formed on the interlayer insulating film IL, and a resist pattern for the narrow contact NC is formed. Specifically, as illustrated in FIG. 32A, in the region where the narrow contact NC is to be formed, by photolithography, so as to achieve the pattern of the narrow contact NC described above, the resist RS is patterned on the interlayer insulating film IL. Moreover, by dry etching, the interlayer insulating film IL is removed from each opening of the pattern of the resist RS at a fixed depth, and the contact hole CH2 for the narrow contact NC is formed. The bottom portion of the contact hole CH2 is formed so as to be located in the interlayer insulating film IL. At this time, as illustrated in FIG. 32B, in the region where the source contact SC is to be formed, the resist RS is formed on the source contact SC and the interlayer insulating film IL.

Next, as illustrated in FIG. 33A and FIG. 33B, by ashing or wet etching, the pattern of the resist RS is removed. As illustrated in FIG. 33A, in the region where the narrow contact NC is to be formed, the patterns of the resist RS in the contact hole CH2 for the narrow contact NC and the resist RS on the interlayer insulating film IL are removed. At the same time, as illustrated in FIG. 33B, in the region where the source contact SC is to be formed, the pattern of the resist RS on the source contact SC and the interlayer insulating film IL is removed.

Subsequently, as illustrated in FIG. 34A and FIG. 34B, the narrow contact NC and the source wire SW are formed. Specifically, the narrow contact NC and the barrier metal layer BM are formed at the same time. In this example, the narrow contact NC and the barrier metal layer BM include the same material and are formed in an integrated manner. Forming the narrow contact NC and the barrier metal layer BM as one body further enhances the anchor effect. As illustrated in FIG. 34A and FIG. 34B, by sputtering or the CVD, in the region where the source contact SC is formed, the barrier metal layer BM including TiW is formed on the source contact SC and the interlayer insulating film IL. At the same time, in the region where the narrow contact NC is to be formed, the barrier metal layer BM including TiW is formed to bury the contact hole CH2 and on the interlayer insulating film IL, so that the narrow contact NC and the barrier metal layer BM are formed in an integrated manner. Then, by sputtering or the CVD, in each of the regions where the source contact SC is formed and the narrow contact NC is formed, an aluminum layer AL is formed on the entire surface of the barrier metal layer BM.

As described above, in the present embodiment, the narrow contact having no electrical connection is disposed in the region including the outer peripheral end portion of the source wire. Owing to the anchor effect of this narrow contact, as in the first embodiment, it is possible to prevent separation of the source wire at the outer peripheral end portion of the source wire. Since the narrow contact does not affect the characteristics of the MOSFET, the narrow contact can be disposed at a freely selected position.

### Third Embodiment

Next, a third embodiment will be described. The present embodiment is an example of variation of the extension direction of the narrow contact illustrated in the second embodiment.

FIG. 35 is an enlarged plan view of the cell region end portion of the semiconductor device 100 according to the present embodiment. FIG. 35 is an enlarged plan view of the cell region end portion 10a of FIG. 3. FIG. 36 is a cross-sectional view taken along a line A5-A5′ in FIG. 35.

As illustrated in FIG. 35, in the present embodiment, the narrow contact NC is disposed so as to extend in parallel to the outer peripheral end portion 11b of the source wire SW. For example, it can also be said that the X direction (second direction) in FIG. 35 is referred to as a lateral direction and that the narrow contact NC extends in the lateral direction. The lateral direction is the same direction as the direction in which the outer peripheral end portion 11b of the source wire SW extends, that is, the same direction as the outer peripheral direction and is the direction perpendicular to the extension direction of the source contact SC. The narrow contact NC according to the present embodiment is also referred to as the lateral narrow contact NC. Note that the narrow contact NC may be disposed not only in the lateral direction, but also in an oblique direction relative to the outer peripheral end portion 11b of the source wire SW.

As illustrated in FIG. 36, as in the second embodiment, the narrow contact NC is shallower than the source contact SC and has a depth reaching the interior of the interlayer insulating film IL, but not passing through the interlayer insulating film IL. Note that configurations other than the layout of the narrow contact NC are the same as those in the second embodiment. The method of manufacturing the narrow contact NC is the same as that of the second embodiment.

The layout position of the lateral narrow contact NC is set to a range necessary for preventing separation of the source wire SW (for example, separation at the region 12 in FIG. 4). For example, the layout position of the lateral narrow contact NC is set to an inner range 13c. The inner range 13c is a predetermined range from an outer side (the vicinity) of the region of the outer end portion 11a of the source contact SC to the outer peripheral end portion 11b of the source wire SW. As in the second embodiment, depending on the size and the material of the source wire SW, the material of the narrow contact NC, and the like, the inner range 13c may be set.

In the example of FIG. 35, the lateral narrow contact NC is disposed halfway between the outer peripheral end portion 11b of the source wire SW and the outer end portion 11a of the source contact SC. According to this layout, as in the second embodiment, owing to the anchor effect of the narrow contact NC extending in the outer peripheral direction around the outer peripheral end portion 11b of the source wire SW, separation of the outer peripheral portion of the source wire SW can be prevented.

FIG. 37 and FIG. 38 are layout examples of a case in which the position of the lateral narrow contact NC is changed. In the example of FIG. 37, the lateral narrow contact NC is located at the same position as the outer peripheral end portion 11b of the source wire SW, in plan view. Specifically, the lateral narrow contact NC may overlap with the vicinity of the outer peripheral end portion 11b of the source wire SW, or the region including the outer peripheral end portion 11b of the source wire SW (the outer peripheral portion), in plan view. In the example of FIG. 38, the lateral narrow contact NC is disposed in the vicinity of the outer end portion 11a of the source contact SC. Even in this case, owing to the anchor effect of the narrow contact NC extending in the outer peripheral direction of the source wire SW, separation of the outer peripheral portion of the source wire SW can be prevented. Disposing the lateral narrow contact at a position closer to the outer peripheral end portion 11b of the source wire SW makes it possible to prevent separation of the end portion of the source wire SW.

FIG. 39 and FIG. 40 are layout examples of a case in which the lateral narrow contact NC is divided into two portions. Specifically, the narrow contact NC may include a first narrow contact portion (first anchor member portion) and a second narrow contact portion (second anchor member portion) which are spaced apart from each other. In the example of FIG. 39, as in FIG. 37, the lateral narrow contact NC is disposed at the same position as the outer peripheral end portion 11b of the source wire SW, in plan view, and moreover, the lateral narrow contact NC is divided into two portions. In the example of FIG. 40, as in FIG. 38, the lateral narrow contact NC is disposed in the vicinity of the outer end portion 11a of the source contact SC, and moreover, the lateral narrow contact NC is divided into two portions. Dividing the narrow contact NC into two portions to be spaced apart from each other enables not only reduction in material costs, but also prevention of separation of the outer peripheral portion of the source wire SW owing to the anchor effect of the narrow contact NC.

FIG. 41 and FIG. 42 are layout examples of a case in which two lateral narrow contacts NC are disposed. Specifically, the first narrow contact NC (first anchor member) and the second narrow contact NC (second anchor member) may be disposed so as to extend in parallel with each other along the outer peripheral direction of the source wire SW, in plan view. Note that the number of the narrow contacts NC to be disposed is not limited to two, and many more narrow contacts NC may be disposed. In the example of FIG. 41, as in FIG. 37, the lateral narrow contact NC is disposed at the same position as the outer peripheral end portion 11b of the source wire SW, in plan view, and moreover, the lateral narrow contact NC is added halfway between the outer peripheral end portion 11b of the source wire SW and the outer end portion 11a of the source contact SC. In the example of FIG. 42, as in FIG. 38, the lateral narrow contact NC is disposed in the vicinity of the outer end portion 11a of the source contact SC, and moreover, the lateral narrow contact NC is added halfway between the outer peripheral end portion 11b of the source wire SW and the outer end portion 11a of the source contact SC. Disposing a plurality of the narrow contacts NC further enhances the anchor effect of the narrow contact NC, thereby preventing separation of the outer peripheral portion of the source wire SW more reliably.

FIG. 43 to FIG. 46 are layout examples of a case in which the two lateral narrow contacts NC are each divided into two portions. In FIG. 43 and FIG. 44, as in FIG. 41, in plan view, the lateral narrow contacts NC are each disposed at the same position as the outer peripheral end portion 11b of the source wire SW and halfway between the outer peripheral end portion 11b of the source wire SW and the outer end portion 11a of the source contact SC. Moreover, as in FIG. 39, the two lateral narrow contacts NC are each divided into two portions. In FIG. 43, the divided narrow contacts NC overlap with each other in the longitudinal direction (Y direction) and are disposed side by side. Specifically, the narrow contact NC portion divided from the first narrow contact NC is disposed to be opposed to the narrow contact NC portion divided from the second narrow contact NC. In FIG. 44, the divided narrow contacts NC do not overlap with each other in the longitudinal direction and are disposed in a staggered (zig-zag) manner. Specifically, an interval region between the narrow contact NC portions divided from the first narrow contact NC is disposed to be opposed to the narrow contact NC portion divided from the second narrow contact NC. In FIG. 45 and FIG. 46, as in FIG. 42, the lateral narrow contacts NC are each disposed in the vicinity of the outer end portion 11a of the source contact SC and halfway between the outer peripheral end portion 11b of the source wire SW and the outer end portion 11a of the source contact SC. Moreover, as in FIG. 40, the two lateral narrow contacts NC are each divided into two portions. In FIG. 45, as in FIG. 43, the divided narrow contacts NC overlap with each other in the longitudinal direction and are disposed side by side. In FIG. 46, as in FIG. 44, the divided narrow contacts NC do not overlap with each other in the longitudinal direction and are disposed in a staggered manner. Also in the cases in FIG. 43 to FIG. 46, disposing a plurality of the narrow contacts NC to be spaced apart from each other enables reduction in material costs, and moreover, owing to the anchor effect of the narrow contact NC, separation of the outer peripheral portion of the source wire SW can be prevented. Note that the longitudinal narrow contact in the second embodiment and the lateral narrow contact in the present embodiment may be used in combination. For example, the divided lateral narrow contacts in each of FIG. 43 to FIG. 46 may be connected with each other by the longitudinal narrow contact.

As described above, in the present embodiment, the narrow contact is disposed in parallel with the outer peripheral end portion of the source wire. Also in this case, as in the second embodiment, it is possible to prevent separation of the source wire at the outer peripheral end portion of the source wire. In addition, the narrow contact is added in a direction being rotated at 90° from the source contact SC, so that warpage of a wafer (the semiconductor substrate) can be improved.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, in the semiconductor device according to the embodiment described above, a configuration in which the conductive type (P type or N type) of each of a semiconductor substrate, a semiconductor layer, a diffusion layer (diffusion region), and the like is inverted may be adopted. As such, in a case in which either one of the N type and the P type is set to the first conductive type and the other one is set to the second conductive type, the first conductive type can be set to the P type, and the second conductive type can also be set to the N type. Conversely, the first conductive type can be set to the N type, and the second conductive type can also be set to the P type.

What is claimed is:

1. A semiconductor device comprising:
a semiconductor substrate;
an insulating film formed on the semiconductor substrate;
an electrode formed on the insulating film; and
an anchor member which is in contact with the insulating film and the electrode at an outer peripheral portion of the electrode, in plan view.

2. The semiconductor device according to claim 1,
wherein the anchor member includes a contact which electrically connects the semiconductor substrate with the electrode.

3. The semiconductor device according to claim 1,
wherein the anchor member is formed so as to pass through the insulating film from a side of the electrode to a side of the semiconductor substrate.

4. The semiconductor device according to claim 1,
wherein the anchor member is formed from a side of the electrode to an interior of the insulating film.

5. The semiconductor device according to claim 1,
wherein the anchor member extends from an inner side of the electrode to an outer side thereof, in plan view.

6. The semiconductor device according to claim 5,
wherein an outer end of the anchor member overlaps with the outer peripheral portion of the electrode, in plan view.

7. The semiconductor device according to claim 5,
wherein an outer end of the anchor member is included in a region outside the outer peripheral portion of the electrode, in plan view.

8. The semiconductor device according to claim 5,
wherein an inner end of the anchor member is included in a region in which a contact which electrically connects the semiconductor substrate with the electrode is formed.

9. The semiconductor device according to claim 5,
wherein an inner end of the anchor member is included in a range from a region in which a contact which electrically connects the semiconductor substrate with the electrode is formed to the outer peripheral portion of the electrode.

10. The semiconductor device according to claim 5,
wherein the anchor member includes a first anchor member portion and a second anchor member portion which are spaced apart from each other, and
wherein either one of the first anchor member portion or the second anchor member portion overlaps with the outer peripheral portion of the electrode, in plan view.

11. The semiconductor device according to claim 1,
wherein the anchor member extends in an outer peripheral direction of the electrode, in plan view.

12. The semiconductor device according to claim 11,
wherein the anchor member is included in a range from a region in which a contact which electrically connects the semiconductor substrate with the electrode is formed to the outer peripheral portion of the electrode.

13. The semiconductor device according to claim 11,
wherein the anchor member includes a first anchor member portion and a second anchor member portion which are spaced apart from each other.

14. The semiconductor device according to claim 11,
wherein the anchor member includes a first anchor member and a second anchor member which extend in parallel with each other along the outer peripheral direction of the electrode, in plan view.

15. The semiconductor device according to claim 14,
wherein each of the first anchor member and the second anchor member includes a plurality of anchor member portions which are spaced apart from each other, and
wherein the plurality of anchor member portions included in the first anchor member and the plurality of anchor member portions included in the second anchor member are opposed to each other.

16. The semiconductor device according to claim 14,
wherein each of the first anchor member and the second anchor member includes a plurality of anchor member portions which are spaced apart from each other, and
wherein an interval region between adjacent ones of the plurality of anchor member portions included in the first anchor member is opposed to each of the plurality of anchor member portions included in the second anchor member.

17. The semiconductor device according to claim 1,
wherein a material of the anchor member includes any of titanium, titanium nitride, tungsten, or titanium tungsten.

18. A method of manufacturing a semiconductor device, comprising:
forming an insulating film on a semiconductor substrate;
forming an electrode on the insulating film; and
forming an anchor member which is in contact with the insulating film and the electrode at an outer peripheral portion of the electrode, in plan view.

19. The method of manufacturing the semiconductor device according to claim 18,
wherein the forming the anchor member includes forming a contact which electrically connects the semiconductor substrate with the electrode, and an anchor member at a same time.

20. The method of manufacturing the semiconductor device according to claim 18,
wherein the forming the anchor member includes forming the anchor member after forming a contact which electrically connects the semiconductor substrate with the electrode.
